(19) United States
(12) Patent Application Publication
(10) Pub. No.: US 2025/0159885 A1
(43) Pub. Date: May 15, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: JUNGYEOM KIM, Suwon-si (KR); HYUNMIN KIM, Suwon-si (KR); JUSEONG MIN, Suwon-si (KR); DONGSIK OH, Suwon-si (KR); KANGOH YUN, Suwon-si (KR); TAEKKYU YOON, Suwon-si (KR); WONHO CHANG, Suwon-si (KR); SEUNGWOOK CHOI, Suwon-si (KR); JEEHOON HAN, Suwon-si (KR)

(21) Appl. No.: 18/743,326

(22) Filed: Jun. 14, 2024

(30) Foreign Application Priority Data
Nov. 14, 2023 (KR) 10-2023-0157697

(51) Int. Cl. H10B 43/27; H01L 25/065; H10B 41/27; H10B 41/35; H10B 41/40; H10B 43/35; H10B 43/40; H10B 80/00

(52) U.S. Cl. CPC H10B 43/27; H01L 25/0652; H10B 41/27; H10B 41/35; H10B 41/40; H10B 43/35; H10B 43/40; H10B 80/00; H01L 2225/06506

(57) ABSTRACT

A semiconductor device includes a first gate dielectric film on a first channel top surface of a substrate, wherein the first channel top surface is in a first region of the substrate, a first gate electrode on the first gate dielectric film, first offset insulating spacers respectively on opposing sidewalls of each of the first gate dielectric film and the first gate electrode, first main insulating spacers respectively on the opposing sidewalls of the first gate electrode, wherein the first offset insulating spacers are between the first main insulating spacers, and a pair of first source/drain regions in the substrate on opposing sides of the first gate electrode, wherein a top surface of each of the pair of first source/drain regions includes at least two first-voltage substrate step portions having respective surfaces that are lower than the first channel top surface of the substrate in a vertical direction.

### CROSS-REFERENCE TO RELATED APPLICATIONS

This application is based on and claims priority under 35 U.S.C. § 119 to Korean Patent Application No. 10-2023-0157697, filed on Nov. 14, 2023, in the Korean Intellectual Property Office, the disclosure of which is incorporated by reference herein in its entirety.

### BACKGROUND OF THE INVENTION

The inventive concepts relate to a semiconductor device and an electronic system including the same, and more particularly, to a semiconductor device including a transistor and an electronic system including the semiconductor device.

In electronic systems that need data storage, a semiconductor device that stores high-capacity data may be beneficial. Accordingly, to increase the data storage capacity of a semiconductor device, a semiconductor device including a vertical memory device having memory cells arranged three-dimensionally and peripheral circuits configured to drive the vertical memory device has been proposed.

### SUMMARY OF THE INVENTION

The inventive concepts provide a semiconductor device of which reliability may be improved by protecting operations of transistors from adverse effects that may occur during a process of manufacturing transistors located in a peripheral circuit region. The reliability may be improved even when the stacked number of word lines is increased in order to improve integration density in a semiconductor device including memory cells arranged three-dimensionally.

The inventive concepts also provide an electronic system including a semiconductor device of which reliability may be improved by protecting operations of transistors from adverse effects that may occur during a process of manufacturing transistors located in a peripheral circuit region. The reliability may be improved even when the stacked number of word lines is increased in order to improve integration density in a semiconductor device including memory cells arranged three-dimensionally.

According to some aspects of the inventive concepts, there is provided a semiconductor device including a first gate dielectric film on a first channel top surface of a substrate, wherein the first channel top surface is in a first region of the substrate, a first gate electrode on the first gate dielectric film, first offset insulating spacers respectively on opposing sidewalls of each of the first gate dielectric film and the first gate electrode, first main insulating spacers respectively on the opposing sidewalls of the first gate electrode, wherein the first offset insulating spacers are between the first main insulating spacers, and a pair of first source/drain regions in the substrate on opposing sides of the first gate electrode, wherein a top surface of each of the pair of first source/drain regions includes at least two first-voltage substrate step portions having respective surfaces that are lower than the first channel top surface of the substrate in a vertical direction perpendicular to a bottom surface of the substrate, and wherein the at least two first-voltage substrate step portions are at different levels from each other in the vertical direction.

According to some aspects of the inventive concepts, there is provided a semiconductor device including a first transistor in a first region on a substrate, the first transistor having a first operating voltage, and a second transistor in a second region on the substrate, the second transistor having a second operating voltage higher than the first operating voltage, wherein the first transistor includes a first gate dielectric film on a first channel top surface of the substrate, a first gate electrode on the first gate dielectric film, first offset insulating spacers respectively on opposing sidewalls of each of the first gate dielectric film and the first gate electrode, first main insulating spacers respectively on the opposing sidewalls of the first gate electrode, wherein the first offset insulating spacers are between the first main insulating spacers, and a pair of first source/drain regions in the substrate on opposing sides of the first gate electrode, wherein the second transistor includes a second gate dielectric film on a second channel top surface of the substrate, the second gate dielectric film having a greater thickness than the first gate dielectric film in a vertical direction perpendicular to a bottom surface of the substrate, a second gate electrode on the second gate dielectric film, the second gate electrode having a width greater than a width of the first gate electrode in a lateral direction parallel to the bottom surface of the substrate, second offset insulating spacers respectively on opposing sidewalls of each of the second gate dielectric film and the second gate electrode, second main insulating spacers respectively on the opposing sidewalls of the second gate electrode, wherein the second offset insulating spacers are between the second main insulating spacers, and a pair of second source/drain regions in the substrate on opposing sides of the second gate electrode, wherein a top surface of at least one of the pair of first source/drain regions includes at least two substrate step portions that are at different levels from each other in the vertical direction, wherein a top surface of the second gate dielectric film includes a dielectric film step portion, and wherein a level of the dielectric film step portion in the vertical direction is closer to the substrate than a level of an interface between the second gate dielectric film and the second gate electrode in the vertical direction and is farther from the bottom surface of the substrate than a level of the second channel top surface in the vertical direction.

According to some aspects of the inventive concepts, there is provided an electronic system including a main substrate, a semiconductor device on the main substrate, and a controller electrically connected to the semiconductor device on the main substrate, wherein the semiconductor device includes a cell region including a memory cell array, and a peripheral circuit region including a plurality of circuits electrically connected to the memory cell array, wherein the plurality of circuits include a first gate dielectric film on a first channel top surface of a substrate, wherein the first channel top surface is in a first region of the substrate, a first gate electrode on the first gate dielectric film, first offset insulating spacers respectively on opposing sidewalls of each of the first gate dielectric film and the first gate electrode, first main insulating spacers respectively on the opposing sidewalls of the first gate electrode, wherein the first offset insulating spacers are between the first main insulating spacers, and a pair of first source/drain regions in the substrate on opposing sides of the first gate electrode, wherein a top surface of each of the pair of first source/drain regions includes at least two first-voltage substrate step portions having respective surfaces that are lower than the first channel top surface of the substrate in a vertical direction perpendicular to a bottom surface of the substrate, and wherein the at least two first-voltage substrate step portions are at different levels from each other in the vertical direction.

### BRIEF DESCRIPTION OF THE DRAWINGS

Embodiments will be more clearly understood from the following detailed description taken in conjunction with the accompanying drawings, in which:

FIG. 1 is a block diagram of a semiconductor device according to some embodiments;

FIG. 2 is a cross-sectional view of a semiconductor device according to some embodiments;

FIG. 3A is an enlarged cross-sectional view of region “EX1” of FIG. 2;

FIG. 3B is an enlarged cross-sectional view of region “EX2” of FIG. 2;

FIG. 4 is a cross-sectional view of a semiconductor device according to some embodiments;

FIG. 5 is an enlarged cross-sectional view of region “EX22” of FIG. 4;

FIG. 6A is a block diagram of a semiconductor device according to some embodiments;

FIG. 6B is a perspective view of a semiconductor device according to some embodiments;

FIG. 6C is a schematic layout illustrating an example planar arrangement of a partial region of a peripheral circuit structure of a semiconductor device according to some embodiments;

FIG. 7 is a perspective view of a semiconductor device according to some embodiments;

FIGS. 8A and 8B are each a schematic diagram of an electronic system including a semiconductor device according to some embodiments;

FIG. 9 is a perspective view of an electronic system including a semiconductor device according to some embodiments;

FIG. 10A is a cross-sectional view of a semiconductor package according to some embodiments;

FIG. 10B is a cross-sectional view of a semiconductor package according to some embodiments;

FIGS. 11A to 11L are cross-sectional views of a process sequence of a method of manufacturing a semiconductor device, according to some embodiments; and

FIGS. 12A to 12D are cross-sectional views of a process sequence of a method of manufacturing a semiconductor device, according to some embodiments.

### DETAILED DESCRIPTION

Hereinafter, example embodiments will be described in detail with reference to the accompanying drawings. The same reference numerals are used to denote the same elements in the drawings, and repeated descriptions thereof will be omitted.

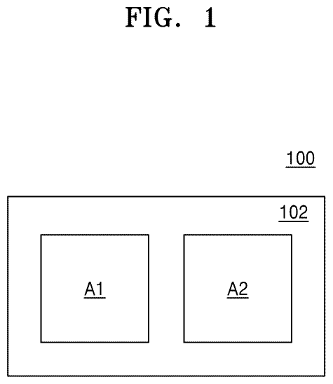

FIG. 1 is a block diagram of a semiconductor device 100 according to some embodiments.

Referring to FIG. 1, the semiconductor device 100 may include a first region A1 and a second region A2, which are on a substrate 102. The first region A1 and the second region A2 may refer to different regions of the substrate 102 or regions configured to perform different operations. The first region A1 and the second region A2 may be regions spaced apart from each other on the substrate 102 in a lateral direction parallel to a main surface of the substrate 102.

In some embodiments, the first region A1 may be a region in which devices operating in a low-power mode are formed, and the second region A2 may be a region in which devices operating in a high-power mode are formed. In some embodiments, the first region A1 may be a region including transistors having a relatively low operating voltage in a range of about 0.5 volts (V) to less than 10 V. The second region A2 may be a region including transistors having a relatively high operating voltage in a range of about 10 V to about 20 V. However, an operating voltage range of transistors in each of the first region A1 and the second region A2 is not limited to the above-described ranges and may vary according to circumstances. In some embodiments, the operating voltage ranges of the first region A1 and the second region A2 may partially overlap each other. As used herein, the first region A1 may also be referred to as a low-voltage transistor region, and the second region A2 may also be referred to as a high-voltage transistor region.

The substrate 102 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon germanium (SiGe). The substrate 102 may be provided as a bulk wafer, an epitaxial layer, a silicon on insulator (SOI) layer, or a semiconductor on insulator (SeOI) layer. As used herein, the substrate 102 may also be referred to as a peripheral circuit substrate.

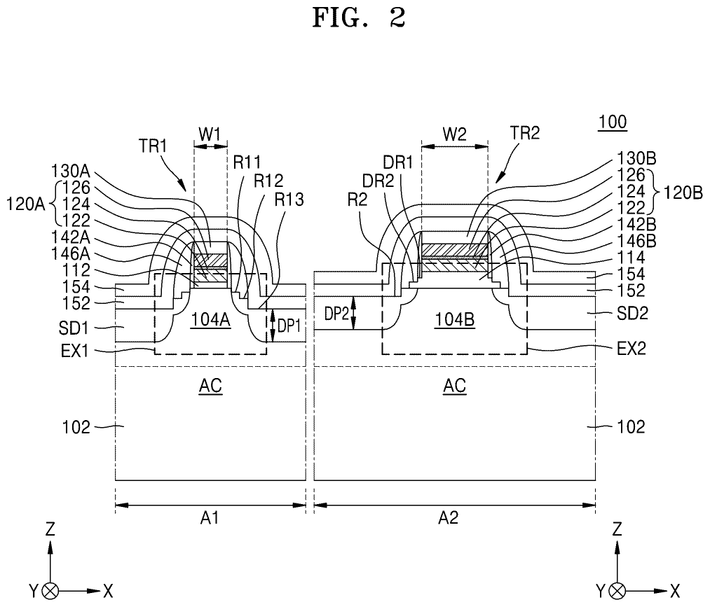

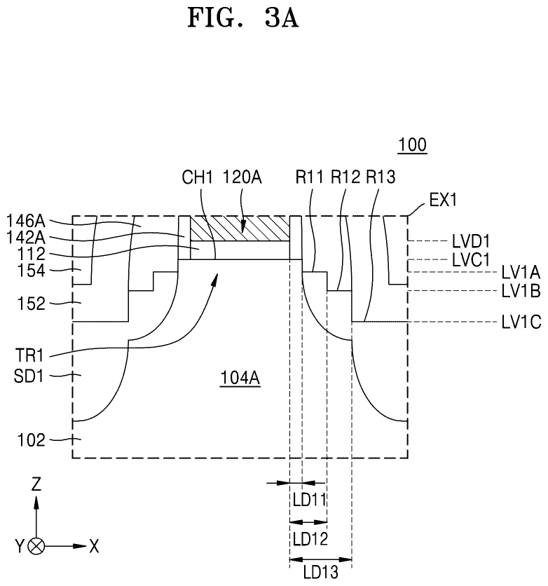

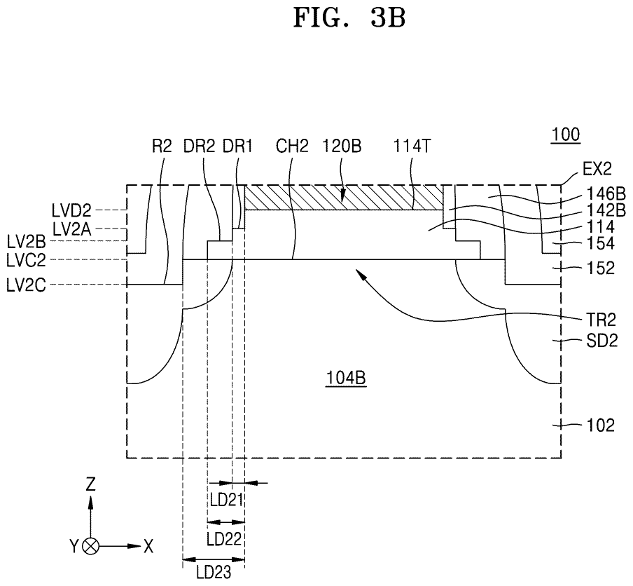

FIG. 2 is a cross-sectional view of a first transistor TR1 located in a first region A1 and a second transistor TR2 located in a second region A2 in a semiconductor device 100. FIG. 3A is an enlarged cross-sectional view of region “EX1” of FIG. 2, and FIG. 3B is an enlarged cross-sectional view of region “EX2” of FIG. 2.

Referring to FIGS. 2, 3A, and 3B, a substrate 102 may include a plurality of active regions AC. A plurality of wells (e.g., 104A and 104B) may be formed in the plurality of active regions AC. Each of the wells 104A and 104B may include an impurity region of the same conductivity type as or a different conductivity type from that of the substrate 102. Each of the wells 104A and 104B may include an impurity region having a different dopant concentration from that of the substrate 102. The wells 104A and 104B may include N-type impurities or P-type impurities according to a conductivity type of a channel of each of the first transistor TR1 and the second transistor TR2.

The first transistor TR1 may have a first operating voltage, and the second transistor TR2 may have a second operating voltage higher than the first operating voltage. For example, the first transistor TR1 may have a first operating voltage, which is a relatively low voltage in a range of about 0.5 V to less than about 10 V. The second transistor TR2 may have a second operating voltage, which is a relatively high voltage in a range of about 10 V to about 20 V. However, an operating voltage range of each of the first transistor TR1 and the second transistor TR2 is not limited to the above-described ranges and may vary according to circumstances.

As shown in FIGS. 2 and 3A, the first transistor TR1 may include a first gate dielectric film 112, a first gate electrode 120A, and a pair of first source/drain regions SD1. The first gate dielectric film 112 may be on a first channel top surface CH1 of the substrate 102 in the first region A1. The first gate electrode 120A may be on the first gate dielectric film 112. The pair of first source/drain regions SD1 may be formed in the substrate 102 on both (e.g., opposing) sides of the first gate electrode 120A. Each of the pair of first source/drain regions SD1 may include an impurity region of a conductivity type opposite to that of the well 104A. In some embodiments, the pair of first source/drain regions SD1 may include a plurality of impurity regions with different dopant concentrations.

In the first transistor TR1, a top surface of the first gate electrode 120A may have a first insulating capping layer 130A thereon. For example, the top surface of the first gate electrode 120A may be covered by the first insulating capping layer 130A. The first transistor TR1 may further include first offset insulating spacers 142A and first main insulating spacers 146A. The first offset insulating spacers 142A may be on (e.g., may cover) both (e.g., opposing) sidewalls of each of the first gate dielectric film 112, the first gate electrode 120A, and the first insulating capping layer 130A. The first main insulating spacers 146A may be on (e.g., may cover) the first offset insulating spacers 142A on the opposing sidewalls of the first gate electrode 120A. That is, the first main insulating spacers 146A may respectively be on the opposing sidewalls of the first gate electrode 120A, and the first offset insulating spacers 142A may be between the first main insulating spacers 146A. The first main insulating spacer 146A may be spaced apart from each of the first gate dielectric film 112, the first gate electrode 120A, and the first insulating capping layer 130A in a lateral direction (e.g., X direction in FIG. 2) with the first offset insulating spacer 142A therebetween. For example, the lateral direction may be parallel to a bottom surface of the substrate 102.

A top surface of each of the pair of first source/drain regions SD1 may include a plurality of substrate step portions (e.g., R11, R12, and R13), which are at different vertical levels that are lower than the first channel top surface CH1. As used herein, the substrate step portions (e.g., R11, R12, and R13) may also be referred to as first-voltage substrate step portions. In the first region A1, the substrate step portions (e.g., R11, R12, and R13) may include a first substrate step portion R11, a second substrate step portion R12, and a third substrate step portion R13, which are at different vertical levels from each other. As used herein, the term “vertical level” (or similar language) refers to a height in a vertical direction (Z direction) with the bottom surface of the substrate 102 providing a base reference plane. That is, a vertical level may be taken in the vertical direction (Z direction) relative to the bottom surface of the substrate 102. For example, the vertical direction may be perpendicular to the bottom surface of the substrate 102.

As shown in FIGS. 2 and 3A, in the first region A1, each of the first to third substrate step portions R11, R12, and R13 may be a separation distance of more than 0 apart from a portion of the substrate 102, which overlaps the first gate electrode 120A in a vertical direction (Z direction), in a lateral direction (e.g., a direction along an X-Y plane). That is, in the first region A1, each of the first to third substrate step portions R11, R12, and R13 may be spaced apart in a lateral direction from a portion of the substrate 102 that overlaps the first gate electrode 120A in a vertical direction. As used herein, “an element A overlaps an element B in a vertical direction” (or similar language) means that there is at least one straight line that extends in the vertical direction and intersects both the elements A and B. In the first region A1, the lateral direction may be a direction parallel to the first channel top surface CH1. For example, the first substrate step portion R11 may be spaced apart by a first separation distance LD11 in the lateral direction from a portion of the substrate 102 that overlaps the first gate electrode 120A in the vertical direction (Z direction). The second substrate step portion R12 may be spaced apart by a second separation distance LD12 in the lateral direction from a portion of the substrate 102 that overlaps the first gate electrode 120A in the vertical direction (Z direction). The second separation distance LD12 may be greater than the first separation distance LD11. The third substrate step portion R13 may be spaced apart by a third separation distance LD13 in the lateral direction from a portion of the substrate 102 that overlaps the first gate electrode 120A in the vertical direction (Z direction). The third separation distance LD13 may be greater than the second separation distance LD12.

In the first region A1, the first to third substrate step portions R11, R12, and R13 may be farther from the first channel top surface CH1 than the first offset insulating spacer 142A in the lateral direction.

In the first region A1, an inner sidewall of the first offset insulating spacer 142A may be in contact with each of the first gate electrode 120A and the first gate dielectric film 112, and an outer sidewall of the first offset insulating spacer 142A may be in contact with the first main insulating spacer 146A. As used herein, the inner sidewall of the first offset insulating spacer 142A may refer to a sidewall facing the first gate electrode 120A, and the outer sidewall of the first offset insulating spacer 142A may refer to a sidewall opposite to the inner sidewall of the first offset insulating spacer 142A. A bottom surface of the first offset insulating spacer 142A may be in contact with the substrate 102. The bottom surface of the first offset insulating spacer 142A, which is in contact with the substrate 102, may be at substantially the same vertical level as a vertical level LVC1 of the first channel top surface CH1.

In the first region A1, each of the first substrate step portion R11 and the second substrate step portion R12 may overlap the first main insulating spacer 146A in the vertical direction (Z direction). The first substrate step portion R11 may be closer to the first channel top surface CH1 than the second substrate step portion R12. A first vertical level LV1A of the first substrate step portion R11 may be closer to a vertical level LVC1 of the first channel top surface CH1 than a second vertical level LV1B of the second substrate step portion R12.

The third substrate step portion R13 may be spaced apart from the first channel top surface CH1 with the first substrate step portion R11 and the second substrate step portion R12 therebetween and may be at a position farther from the first channel top surface CH1 than the first main insulating spacer 146A in a lateral direction (e.g., X direction in FIGS. 2 and 3A).

As shown in FIGS. 2 and 3B, the second transistor TR2 may include a second gate dielectric film 114 on a second channel top surface CH2 of the substrate 102 in the second region A2, a second gate electrode 120B located on the second gate dielectric film 114, and a pair of second source/drain regions SD2 formed in the substrate 102 on both (e.g., opposing) sides of the second gate electrode 120B.

The pair of second source/drain regions SD2 may each include an impurity region of a conductivity type opposite to that of the well 104B. In some embodiments, the pair of second source/drain regions SD2 may include a plurality of impurity regions having different dopant concentrations from each other.

In the second transistor TR2, a top surface of the second gate electrode 120B may have a second insulating capping layer 130B thereon. For example, the top surface of the second gate electrode 120B may be covered by the second insulating capping layer 130B. The second transistor TR2 may further include second offset insulating spacers 142B and second main insulating spacers 146B. The second offset insulating spacers 142B may be on (e.g., may cover) both (e.g., opposing) sidewalls of each of the second gate dielectric film 114, the second gate electrode 120B, and the second insulating capping layer 130B. The second main insulating spacers 146B may be on (e.g., may cover) the second offset insulating spacers 142B on opposing sides of the second gate electrode 120B. That is, the second main insulating spacers 146B may respectively be on the opposing sidewalls of the second gate electrode 120B, and the second offset insulating spacers 142B may be between the second main insulating spacers 146B.

Each of the first gate dielectric film 112 of the first transistor TR1 in the first region A1 and the second gate dielectric film 114 of the second transistor TR2 in the second region A2 may include a silicon oxide film, silicon oxynitride (SiON), germanium oxynitride (GeON), germanium silicon oxide (GeSiO), a high-k dielectric film, or a combination thereof. The high-k dielectric film may be a dielectric film having a higher dielectric constant than a silicon oxide film. In some embodiments, the high-k dielectric film may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiO), hafnium oxide (HfO₂), hafnium silicon oxide (HfSiO), lanthanum oxide (La₂O₃), lanthanum aluminum oxide (LaAlO), lanthanum hafnium oxide (LaHfO), hafnium aluminum oxide (HfAlO), praseodymium oxide (Pr₂O₃), or a combination thereof. For example, each of the first gate dielectric film 112 and the second gate dielectric film 114 may include a silicon oxide film.

In the vertical direction (Z direction), the second gate dielectric film 114 may have a greater thickness than the first gate dielectric film 112. In some embodiments, the first gate dielectric film 112 may have a thickness selected in a range of about 1 angstrom (Å) to about 100 Å (e.g., about 20 Å to about 100 Å), and the second gate dielectric film 114 may have a thickness selected in a range of about 200 Å to about 700 Å (e.g., about 200 Å to about 600 Å), but the inventive concepts are not limited thereto.

Each of the first gate electrode 120A in the first region A1 and the second gate electrode 120B in the second region A2 may include doped polysilicon, a conductive metal-containing film, or a combination thereof. The doped polysilicon may be doped with N-type or P-type impurities. In some embodiments, boron (B), boron fluoride (BF₂), and/or indium (In) may be used as the P-type impurities, and phosphorus (P) or arsenic (As) may be used as the N-type impurities. In some embodiments, the conductive metal-containing film included in each of the first gate electrode 120A and the second gate electrode 120B may include titanium (Ti), titanium nitride (TiN), tungsten (W), tungsten nitride (WN), titanium aluminum (TiAl), titanium aluminum nitride (TiAlN), tantalum (Ta), tantalum nitride (TaN), titanium carbide (TIC), tantalum carbide (TaC), tantalum carbonitride (TaCN), tantalum silicon nitride (TaSiN), cobalt (Co), ruthenium (Ru), copper (Cu), molybdenum (Mo), aluminum (Al), or a combination thereof.

In some embodiments, as shown in FIG. 2, each of the first gate electrode 120A and the second gate electrode 120B may include a doped polysilicon film 122, a conductive barrier film 124, and a metal film 126, which are sequentially stacked on the substrate 102. For example, the conductive barrier film 124 may include TiN, and the metal film 126 may include W, without being limited thereto. A thickness of each of the first gate electrode 120A and the second gate electrode 120B in the vertical direction (Z direction) is not limited to that shown in FIG. 2 and may be variously selected as needed.

In a lateral direction (e.g., X direction in FIG. 2), the first gate electrode 120A may have a first width W1, and the second gate electrode 120B may have a second width W2 that is greater than the first width W1. In the vertical direction (Z direction), a thickness of the first gate electrode 120A of the first transistor TR1 in the first region A1 may substantially equal to a thickness of the second gate electrode 120B of the second transistor TR2 in the second region A2.

In the second region A2, a top surface of each of the pair of second source/drain regions SD2 may include a substrate step portion R2 having a surface at a lower vertical level than the second channel top surface CH2. As used herein, the substrate step portion R2 may also be referred to as a second-voltage substrate step portion.

Each of a first dielectric film step portion DR1, a second dielectric film step portion DR2, and the substrate step portion R2 may be a separation distance of more than 0 apart from a portion of the substrate 102, which overlaps the second gate electrode 120B in the vertical direction (Z direction), in a lateral direction (e.g., a direction along an X-Y plane). That is, each of the first dielectric film step portion DR1, the second dielectric film step portion DR2, and the substrate step portion R2 may be spaced apart in the lateral direction from a portion of the substrate 102 that overlaps the second gate electrode 120B in the vertical direction. In the second region A2, the lateral direction may be a direction parallel to the second channel top surface CH2. For example, the first dielectric film step portion DR1 may be spaced apart by a first separation distance LD21 in the lateral direction from a portion of the substrate 102 that overlaps the second gate electrode 120B in the vertical direction (Z direction). The second dielectric film step portion DR2 may be spaced apart by a second separation distance LD22 in the lateral direction from a portion of the substrate 102 that overlaps the second gate electrode 120B in the vertical direction (Z direction). The second separation distance LD22 may be greater than the first separation distance LD21. The substrate step portion R2 may be spaced apart by a third separation distance LD23 in the lateral direction from a portion of the substrate 102 that overlaps the second gate electrode 120B in the vertical direction (Z direction). The third separation distance LD23 may be greater than the second separation distance LD22.

In the second region A2, the substrate step portion R2 may be farther from the second channel top surface CH2 than the second offset insulating spacer 142B and the second main insulating spacer 146B in the lateral direction. In the second region A2, a lowermost surface of the second main insulating spacer 146B may be at substantially the same vertical level as a vertical level LVC2 of the second channel top surface CH2. The second main insulating spacer 146B may have an inner sidewall in contact with the second offset insulating spacer 142B, a surface in contact with the second gate dielectric film 114, and a surface in contact with the substrate 102. For example, the second main insulating spacer 146B may have a surface in contact with the second source/drain region SD2.

In the second region A2, the second gate dielectric film 114 may have a width in a lateral direction (e.g., X direction) that increases toward the substrate 102 in the vertical direction (Z direction) from a top surface 114T of the second gate dielectric film 114, which is in contact with the second gate electrode 120B. Accordingly, a cross-section of the second gate dielectric film 114 in the lateral direction (e.g., X direction in FIGS. 2 and 3B) may have an inverted T shape.

The top surface 114T of the second gate dielectric film 114 may include the first dielectric film step portion DR1 and the second dielectric film step portion DR2, which are at different vertical levels from each other on both sides of the second gate electrode 120B. As used herein, each of the first dielectric film step portion DR1 and the second dielectric film step portion DR2 may also be referred to as a dielectric film step portion.

The first dielectric film step portion DR1 may overlap the second offset insulating spacer 142B in the vertical direction (Z direction). In the vertical direction (Z direction), a vertical level LV2A of the first dielectric film step portion DR1 may be closer to the substrate 102 than a vertical level LVD2 of an interface between the second gate dielectric film 114 and the second gate electrode 120B, and may be farther from the substrate 102 than the vertical level LVC2 of the second channel top surface CH2.

The second dielectric film step portion DR2 may overlap the second main insulating spacer 146B in the vertical direction (Z direction). In the vertical direction (Z direction), a vertical level LV2B of the second dielectric film step portion DR2 may be closer to the substrate 102 than the vertical level LVD2 of the interface between the second gate dielectric film 114 and the second gate electrode 120B, may be closer to the substrate 102 than the vertical level LV2A of the first dielectric film step portion DR1, and may be farther from the substrate 102 than the vertical level LVC2 of the second channel top surface CH2. The second dielectric film step portion DR2 may be farther from the second channel top surface CH2 than the second main insulating spacer 146B in the lateral direction (e.g., X direction in FIG. 2). A vertical level of the lowermost surface of the second main insulating spacer 146B may be closer to the substrate 102 than the vertical level LV2B of the second dielectric film step portion DR2 and may be substantially the same as the vertical level LVC2 of the second channel top surface CH2.

In the first region A1 and the second region A2, the first transistor TR1 and the second transistor TR2 may have a first protective film 152 and a second protective film 154 sequentially thereon. For example, in the first region A1 and the second region A2, the first transistor TR1 and the second transistor TR2 may be sequentially covered by the first protective film 152 and the second protective film 154. The first protective film 152 and the second protective film 154 may include different insulating materials from each other. For example, the first protective film 152 may include a silicon oxide film, and the second protective film 154 may include a silicon nitride film, without being limited thereto.

In the first region A1, a vertical level LV1C of the third substrate step portion R13 may be lower than the vertical level LVC1 of the first channel top surface CH1, may be lower than the vertical level LV1A of the first substrate step portion R11, and may be lower than the vertical level LV1B of the second substrate step portion R12. In the vertical direction (Z direction), the vertical level LV1C of the third substrate step portion R13 may be farther from the vertical level LVD1 of an interface between the first gate dielectric film 112 and the first gate electrode 120A than the vertical level LVC1 of the first channel top surface CH1. In the first region A1, the third substrate step portion R13 may overlap the first protective film 152 and the second protective film 154 in the vertical direction (Z direction).

In the second region A2, a vertical level LV2C of the substrate step portion R2 may be lower than the vertical level LVC2 of the second channel top surface CH2. In the vertical direction (Z direction), the vertical level LV2C of the substrate step portion R2 may be farther from the vertical level LVD2 of the interface between the second gate dielectric film 114 and the second gate electrode 120B than the vertical level LVC2 of the second channel top surface CH2. The substrate step portion R2 may overlap the first protective film 152 and the second protective film 154 in the vertical direction (Z direction).

As shown in FIG. 2, in the vertical direction (Z direction), a maximum depth DP1 of the pair of first source/drain regions SD1 may be substantially equal to a maximum depth DP2 of the pair of second source/drain regions SD2. That is, a thickness of the pair of first source/drain regions SD1 may be substantially equal to a thickness of the pair of second source/drain regions SD2 in the vertical direction (Z direction). As shown in FIGS. 2 and 3A, in a portion of the pair of first source/drain regions SD1, which has the maximum depth DP1, a vertical level of the top surface of each of the pair of first source/drain regions SD1 may correspond to the vertical level LV1C of the third substrate step portion R13. As shown in FIGS. 2 and 3B, in a portion of the pair of second source/drain regions SD2, which has the maximum depth DP2, a vertical level of the top surface of each of the pair of second source/drain regions SD2 may correspond to the vertical level LV2C of the substrate step portion R2. In some embodiments, the pair of first source/drain regions SD1 and the pair of second source/drain regions SD2 may each have a lightly doped drain (LDD) structure.

The first insulating capping layer 130A on (e.g., covering) the first gate electrode 120A in the first region A1 may include the same insulating material as the second insulating capping layer 130B on (e.g., covering) the second gate electrode 120B in the second region A2. In some embodiments, each of the first insulating capping layer 130A and the second insulating capping layer 130B may include a silicon nitride film.

Each of the first offset insulating spacer 142A and the second offset insulating spacer 142B may include a silicon nitride film. Each of the first main insulating spacer 146A and the second main insulating spacer 146B may include a silicon oxide film. In the lateral direction (e.g., X direction in FIG. 2), a width of each of the first main insulating spacer 146A and the second main insulating spacer 146B may be greater than a width of each of the first offset insulating spacer 142A and the second offset insulating spacer 142B.

The first transistor TR1 formed in the first region A1 may be adopted as a low-voltage transistor requiring a high-speed operation, from among transistors included in a peripheral circuit region of the semiconductor device 100. The second transistor TR2 formed in the second region A2 may be adopted as a transistor configured to generate or transmit a high voltage, from among transistors included in the peripheral circuit region of the semiconductor device 100.

According to some embodiments, in the semiconductor device 100 described with reference to FIGS. 1 to 3B, the stacked number of word lines may be increased to improve integration density in a semiconductor device including memory cells arranged three-dimensionally. Therefore, even when the number of transistors connected to the memory cells is increased, operations of the transistors may be protected from adverse effects caused by damage that may occur during a process of forming the transistors located in the peripheral circuit region, and thus, a semiconductor device with improved reliability may be provided.

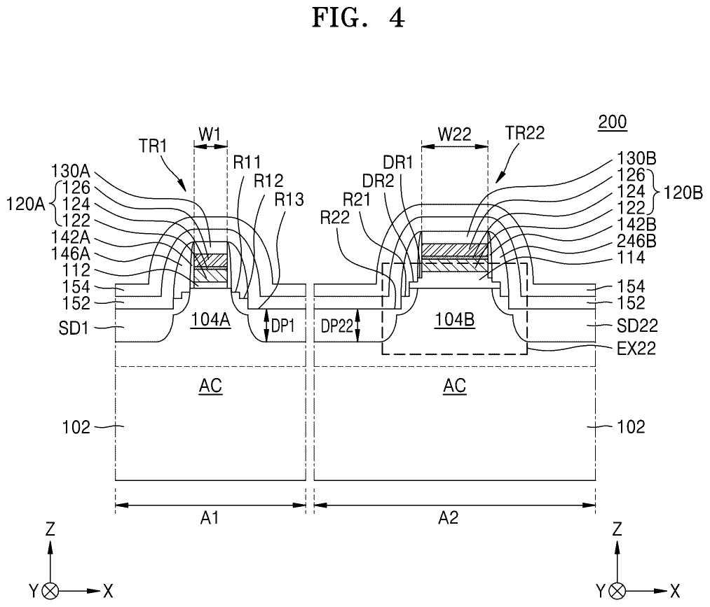

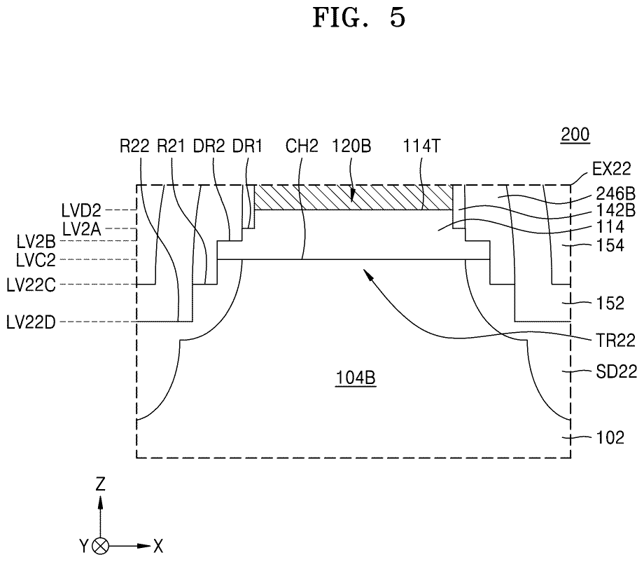

FIG. 4 is a cross-sectional view of a semiconductor device 200 according to some embodiments. FIG. 5 is an enlarged cross-sectional view of region “EX22” of FIG. 4. In FIGS. 4 and 5, the same reference numerals are used to denote the same elements as in FIGS. 1 to 3B, and thus, a detailed description thereof is omitted.

Referring to FIGS. 4 and 5, the semiconductor device 200 may have substantially the same configuration as the semiconductor device 100 described with reference to FIGS. 1 to 3B. However, the semiconductor device 200 may include a second transistor TR22 in a second region A2. The second transistor TR22 may include a pair of second source/drain regions SD22 and a second main insulating spacer 246B. The pair of second source/drain regions SD22 may be formed in the substrate 102 on both (e.g., opposing) sides of the second gate electrode 120B.

The pair of second source/drain regions SD22 may have substantially the same configuration as the pair of second source/drain regions SD2 described with reference to FIGS. 2 and 3B. However, each of the pair of second source/drain regions SD22 may include a first substrate step portion R21 and a second substrate step portion R22, which are at different vertical levels from each other. As used herein, each of the first substrate step portion R21 and the second substrate step portion R22 may also be referred to as a second-voltage substrate step portion.

In the second region A2, the first substrate step portion R21 may overlap the second main insulating spacer 246B in the vertical direction (Z direction). The second substrate step portion R22 may be spaced apart from the second channel top surface CH2 with the first substrate step portion R21 therebetween and may be farther from the second channel top surface CH2 than the second main insulating spacer 246B in a lateral direction (e.g., X direction in FIGS. 4 and 5). In the second region A2, the first substrate step portion R21 may be closer to the second channel top surface CH2 than the second substrate step portion R22. A vertical level LV22C of the first substrate step portion R21 may be closer to a vertical level LVC2 of the second channel top surface CH2 than a vertical level LV22D of the second substrate step portion R22.

The second main insulating spacer 246B may have substantially the same configuration as the second main insulating spacer 146B described with reference to FIGS. 2 and 3B. However, a lowermost surface of the second main insulating spacer 246B may be at a vertical level lower than the vertical level LVC2 of the second channel top surface CH2. The lowermost surface of the second main insulating spacer 246B may be at substantially the same level as the vertical level LV22C of the first substrate step portion R21. The lowermost surface of the second main insulating spacer 246B may be in contact with the first substrate step portion R21. The second main insulating spacer 246B may include a portion that protrudes toward the substrate 102 at a vertical level higher than the vertical level LVC2 of the second channel top surface CH2. The second main insulating spacer 246B may include an inner sidewall in contact with the second offset insulating spacer 142B, a surface in contact with the second gate dielectric film 114, and a surface in contact with the substrate 102. For example, the second main insulating spacer 246B may include a surface in contact with the second source/drain region SD22.

In the vertical direction (Z direction), the vertical level LV22D of the second substrate step portion R22 may be farther from the vertical level LVD2 of the interface between the second gate dielectric film 114 and the second gate electrode 120B than the vertical level LVC2 of the second channel top surface CH2 and the vertical level LV22C of the first substrate step portion R21. The second substrate step portion R22 may overlap the first protective film 152 and the second protective film 154 in the vertical direction (Z direction).

As shown in FIG. 4, in the vertical direction (Z direction), a maximum depth DP1 of the pair of first source/drain regions SD1 may be substantially equal to a maximum depth DP22 of the pair of second source/drain regions SD22. That is, a thickness of the pair of first source/drain regions SD1 may be substantially equal to a thickness of the pair of second source/drain regions SD22 in the vertical direction (Z direction). As shown in FIGS. 4 and 5, in a portion of the pair of second source/drain regions SD22, which has the maximum depth DP22, a vertical level of a top surface of each of the pair of second source/drain regions SD22 may correspond to the vertical level LV22D of the second substrate step portion R22.

According to some embodiments, in the semiconductor device 200 described with reference to FIGS. 4 and 5, the stacked number of word lines may be increased to improve integration density in a semiconductor device including memory cells arranged three-dimensionally. Therefore, even when the number of transistors connected to the memory cells is increased, operations of the transistors may be protected from adverse effects caused by damage that may occur during a process of forming transistors located in a peripheral circuit region, and thus, a semiconductor device with improved reliability may be provided.

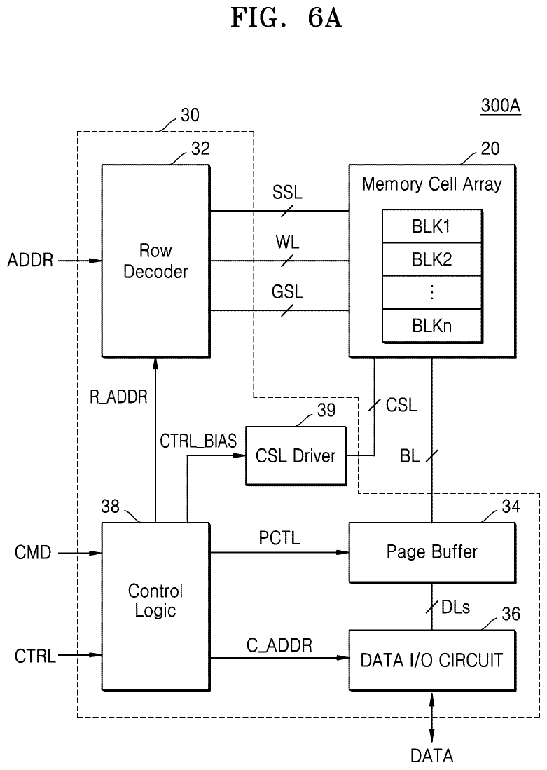

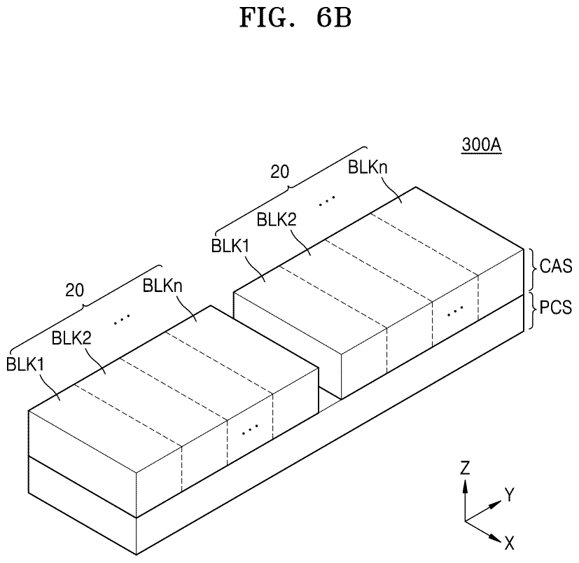

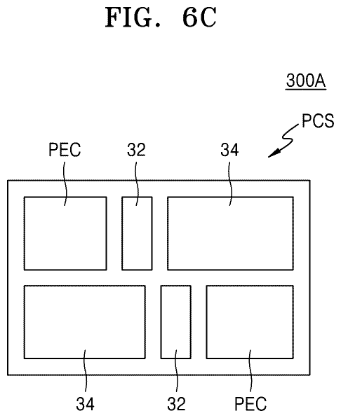

FIG. 6A is a block diagram of a semiconductor device 300A according to some embodiments.

Referring to FIG. 6A, the semiconductor device 300A may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The memory cell blocks BLK1, BLK2, . . . , and BLKn may be connected to the peripheral circuit 30 through a bit line BL, a word line WL, a string selection line SSL, and a ground selection line GSL. As used herein, “an element A connected to an element B” (or similar language) means that the element A is physically and/or electrically connected to the element B.

The peripheral circuit 30 may include a row decoder 32, a page buffer 34, a data input/output (I/O) circuit 36, a control logic 38, and a common source line (CSL) driver 39. Although not shown in FIG. 6A, the peripheral circuit 30 may further include a voltage generation circuit configured to generate various voltages required for operations of the semiconductor device 300A, an error correction circuit configured to correct errors in data read from the memory cell array 20, and an I/O interface.

The memory cell array 20 may be connected to the row decoder 32 through the word line WL, the string selection line SSL, and the ground selection line GSL and may be connected to the page buffer 34 through the bit line BL. In the memory cell array 20, each of the plurality of memory cells included in the plurality of memory cell blocks BLK1, BLK2, . . . , and BLKn may be a flash memory cell. The memory cell array 20 may include a three-dimensional (3D) memory cell array. The 3D memory cell array may include a plurality of NAND strings, and each of the plurality of NAND strings may include a plurality of memory cells connected to a plurality of word lines WL, which are vertically stacked.

The peripheral circuit 30 may receive an address ADDR, a command CMD, and a control signal CTRL from the outside of the semiconductor device 300A and transmit and receive data DATA to and from a device located outside the semiconductor device 300A (i.e., an external device).

The row decoder 32 may select at least one from the plurality of memory cell blocks BLK1, BLK2, . . . , and BLKn in response to the address ADDR provided from the outside, and select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. During a program operation, the page buffer 34 may operate as a write driver and apply a voltage corresponding to data DATA to be stored in the memory cell array 20 to the bit line BL. During a read operation, the page buffer 34 may operate as a sense amplifier and sense the data DATA stored in the memory cell array 20. The page buffer 34 may operate in response to a control signal PCTL provided from the control logic 38.

The data I/O circuit 36 may be connected to the page buffer 34 through a plurality of data lines DLs. During the program operation, the data I/O circuit 36 may receive data DATA from a memory controller (not shown) and provide program data DATA to the page buffer 34 based on a column address C_ADDR provided from the control logic 38. During the read operation, the data I/O circuit 36 may provide read data DATA stored in the page buffer 34 to the memory controller based on the column address C_ADDR provided from the control logic 38.

The data I/O circuit 36 may transmit an input address ADDR or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide a column address C_ADDR to the data I/O circuit 36. The control logic 38 may generate various internal control signals used in the semiconductor device 300A in response to the control signal CTRL. For example, the control logic 38 may adjust voltage levels provided to the word line WL and the bit line BL during the memory operation, such as the program operation or the erase operation.

The CSL driver 39 may be connected to the memory cell array 20 through the common source line CSL. The CSL driver 39 may apply a common source voltage (e.g., a power supply voltage) or a ground voltage to the common source line CSL via the control of the control logic 38 (e.g., in response to a control bias signal CTRL_BIAS).

FIG. 6B is a perspective view of a semiconductor device 300A according to some embodiments.

Referring to FIG. 6B, the semiconductor device 300A may include a cell array structure CAS and a peripheral circuit structure PCS, which overlap each other in a vertical direction (Z direction). The cell array structure CAS may include a memory cell array 20 described with reference to FIG. 6A. The peripheral circuit structure PCS may include a peripheral circuit 30 described with reference to FIG. 6A. As used herein, the cell array structure CAS may also be referred to as a cell region, and the peripheral circuit structure PCS may also be referred to as a peripheral circuit region.

In some embodiments, the peripheral circuit 30 may include a plurality of metal-oxide-semiconductor (MOS) transistors, which may be classified according to magnitudes of operating voltages thereof and distributed in a plurality of transistor regions. For example, the peripheral circuit 30 may include a low-voltage region in which a plurality of low-voltage MOS transistors are formed and a high-voltage region in which a plurality of high-voltage MOS transistors are formed. In addition, the peripheral circuit 30 may include various regions that include MOS transistors having operating voltages higher than the operating voltage of the MOS transistor located in the low-voltage region and lower than the operating voltage of the MOS transistor located in the high-voltage region.

FIG. 6C is a schematic layout illustrating an example planar arrangement of a partial region of a peripheral circuit structure PCS of a semiconductor device 300A according to some embodiments.

Referring to FIG. 6C, the peripheral circuit structure PCS may include a row decoder 32, a page buffer 34, and a plurality of peripheral circuits PEC. The plurality of peripheral circuits PEC may include various circuits included in the peripheral circuit 30 shown in FIG. 6A. For example, the plurality of peripheral circuits PEC may include a data I/O circuit 36, a control logic 38, a voltage generator configured to generate a word line voltage, a latch circuit, a cache circuit, a sense amplifier, and an electrostatic discharge (ESD) device. In some embodiments, the data I/O circuit 36 may be in a peripheral region of the plurality of peripheral circuits PEC. The page buffer 34 and the plurality of peripheral circuits PEC may overlap a memory cell array (refer to 20 in FIG. 6A) in a vertical direction. The planar arrangement illustrated in FIG. 6C is merely an example and may be variously modified and changed within the scope of the inventive concepts.

The peripheral circuit structure PCS shown in FIGS. 6B and 6C may include at least one of the first transistor TR1 and the second transistor TR2 or TR22, which are described with reference to FIGS. 1 to 5. In some embodiments, at least some of transistors included in the data I/O circuit 36 described with reference to FIG. 6A may have a structure of the first transistor TR1 described with reference to FIGS. 1 to 5. In some embodiments, at least one of the circuits included in the peripheral circuit 30 described with reference to FIG. 6A may include the second transistor TR2 shown in FIGS. 2 and 3B or the second transistor TR22 shown in FIGS. 4 and 5. As an example, at least some of transistors that are included in the row decoder 32, the page buffer 34, and a common source line driver 39 that are described above with reference to FIGS. 6A and 6C may include the second transistor TR2 shown in FIGS. 2 and 3B or the second transistor TR22 shown in FIGS. 4 and 5. In some other embodiments, the row decoder 32 shown in FIGS. 6A and 6C may include a high-voltage switch to which a high voltage higher than a power supply voltage is applied from the outside (i.e., externally). A high voltage of about 20 V may be used during a program operation or erase operation of a memory cell included in the memory cell array 20 shown in FIG. 6A. Also, to control the high voltage, an external high voltage may be applied to the high-voltage switch. The high-voltage switch may include the second transistor TR2 shown in FIGS. 2 and 3B or the second transistor TR22 shown in FIGS. 4 and 5.

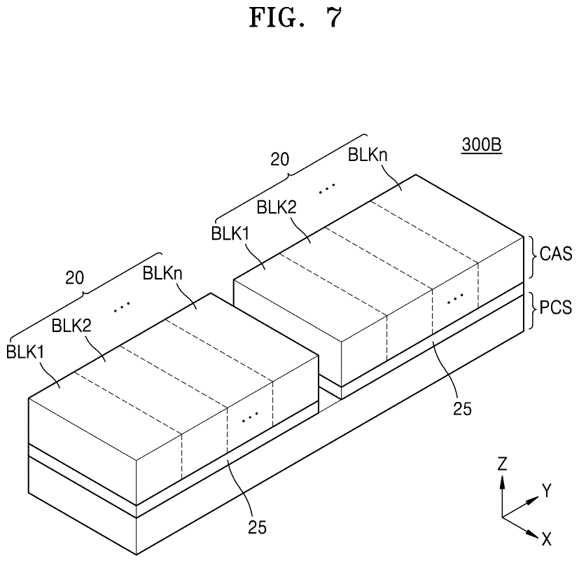

FIG. 7 is a perspective view of a semiconductor device 300B according to some embodiments. In FIG. 7, the same reference numerals are used to denote the same elements as in FIGS. 6A to 6C, and thus, a detailed description thereof is omitted.

Referring to FIG. 7, the semiconductor device 300B may have substantially the same configuration as the semiconductor device 300A described with reference to FIGS. 6A to 6C. The semiconductor device 300B may include a cell array structure CAS and a peripheral circuit structure PCS, which overlap each other in a vertical direction (Z direction). However, the semiconductor device 300B may further include a connection structure 25 between the cell array structure CAS and the peripheral circuit structure PCS. The cell array structure CAS and the peripheral circuit structure PCS may be stacked in the vertical direction (Z direction) through the connection structure 25. The connection structure 25 may provide physical connection and electrical connection between the cell array structure CAS and the peripheral circuit structure PCS. The connection structure 25 may enable electrical connection and data transmission between the cell array structure CAS and the peripheral circuit structure PCS. The connection structure 25 may include a plurality of connection units configured to electrically connect the cell array structure CAS to the peripheral circuit structure PCS. The plurality of connection units may include a connection unit including a metal-metal bonding structure, a through-silicon via (TSV), a back via stack (BVS), a eutectic bonding structure, a ball grid array (BGA) bonding structure, a plurality of wiring lines, a plurality of contact plugs, or a combination thereof. In some embodiments, the metal-metal bonding structure may include copper (Cu), aluminum (Al), tungsten (W), or a combination thereof.

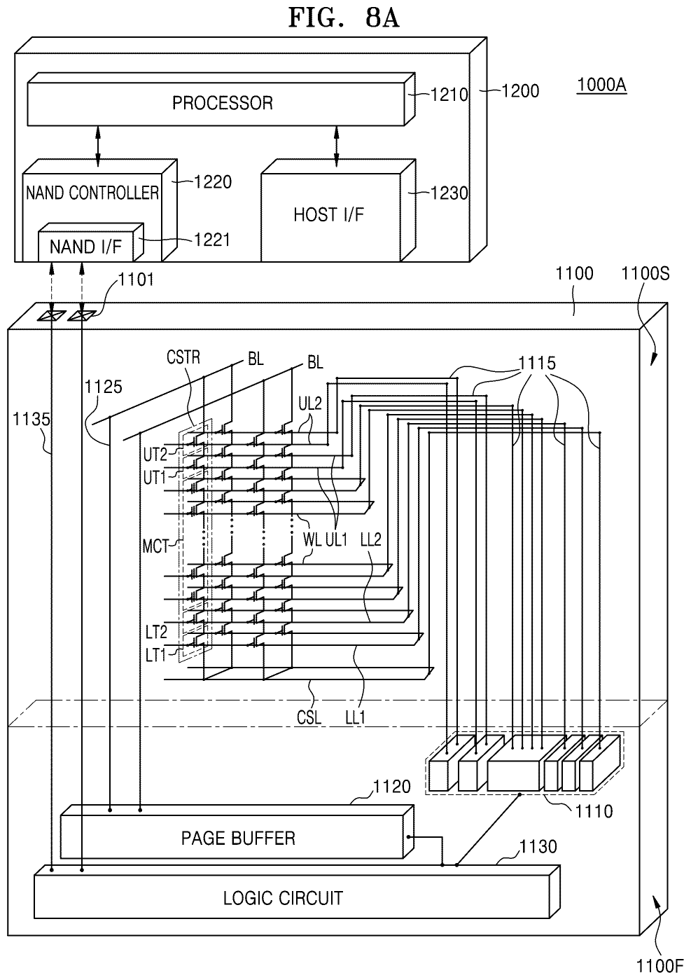

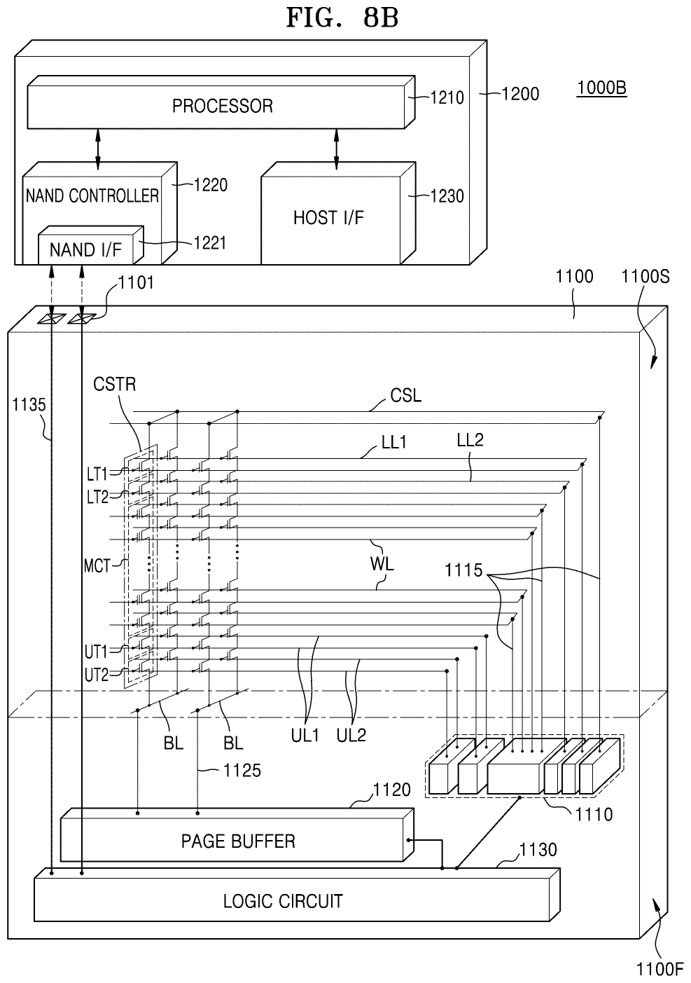

FIGS. 8A and 8B are each a schematic diagram of an electronic system including a semiconductor device according to some embodiments.

Referring to FIGS. 8A and 8B, each of electronic systems 1000A and 1000B may include a semiconductor device 1100 and a controller 1200 electrically connected to the semiconductor device 1100. Each of the electronic systems 1000A and 1000B may be a storage device including at least one semiconductor device 1100 or an electronic device including the storage device. For example, each of the electronic systems 1000A and 1000B may be a solid-state drive (SSD) device, a universal serial bus (USB), a computing system, a medical device, or a communication device, which includes the at least one semiconductor device 1100.

The semiconductor device 1100 may be a non-volatile memory device. For example, the semiconductor device 1100 may be a NAND flash memory device including at least one of the structures of the semiconductor devices 100, 200, 300A, and 300B, which are described above with reference to FIGS. 1 to 7. The semiconductor device 1100 may include a first structure 1100F and a second structure 1100S on the first structure 1100F. In some embodiments, although not shown, the first structure 1100F may be beside the second structure 1100S. The first structure 1100F may be a peripheral circuit structure including a decoder circuit 1110, a page buffer 1120, and a logic circuit 1130. The second structure 1100S may include a memory cell structure, which includes a bit line BL, a common source line CSL, a plurality of word lines WL, first and second gate upper lines (e.g., UL1 and UL2), first and second gate lower lines (e.g., LL1 and LL2), and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors (e.g., LT1 and LT2) and the number of upper transistors (e.g., UT1 and UT2) may be variously modified and are not limited to that shown.

In some embodiments, the upper transistors UT1 and UT2 may include string selection transistors, and the lower transistors LT1 and LT2 may include ground selection transistors. A plurality of gate lower lines (e.g., LL1 and LL2) may be gate electrodes of the lower transistors LT1 and LT2, respectively. The word line WL may be a gate electrode of the memory cell transistor MCT, and the gate upper lines UL1 and UL2 may be gate electrodes of the upper transistor UT1 and UT2, respectively.

The common source line CSL, the plurality of gate lower lines (e.g., LL1 and LL2), the plurality of word lines WL, and a plurality of gate upper lines (e.g., UL1 and UL2) may be electrically connected to the decoder circuit 1110 through a plurality of first connection wiring layers 1115 that extend to the second structure 1100S from the first structure 1100F. The plurality of bit lines BL may be electrically connected to the page buffer 1120 through a plurality of second connection wiring layers 1125 that extend to the second structure 1100S from the first structure 1100F.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 through an I/O pad 1101 electrically connected to the logic circuit 1130. The I/O pad 1101 may be electrically connected to the logic circuit 1130 through an I/O connection wiring layer 1135 that extends to the second structure 1100S from the first structure 1100F.

The controller 1200 may include a processor 1210, a NAND controller 1220, and a host interface (I/F) 1230. In some embodiments, each of the electronic systems 1000A and 1000B may include a plurality of semiconductor devices 1100. In this case, the controller 1200 may control the plurality of semiconductor devices 1100.

The processor 1210 may control all operations of each of the electronic systems 1000A and 1000B, which includes the controller 1200. The processor 1210 may operate according to predetermined firmware, may control the NAND controller 1220, and may access the semiconductor device 1100. The NAND controller 1220 may include a NAND I/F 1221 configured to process communications with the semiconductor device 1100. A control command for controlling the semiconductor device 1100, data to be written to the plurality of memory cell transistors MCT of the semiconductor device 1100, and data to be read from the plurality of memory cell transistors MCT of the semiconductor device 1100 may be transmitted through the NAND I/F 1221. The host interface 1230 may provide a communication function between each of the electronic systems 1000A and 1000B and an external host. When the control command is received from the external host through the host I/F 1230, the processor 1210 may control the semiconductor device 1100 in response to the control command.

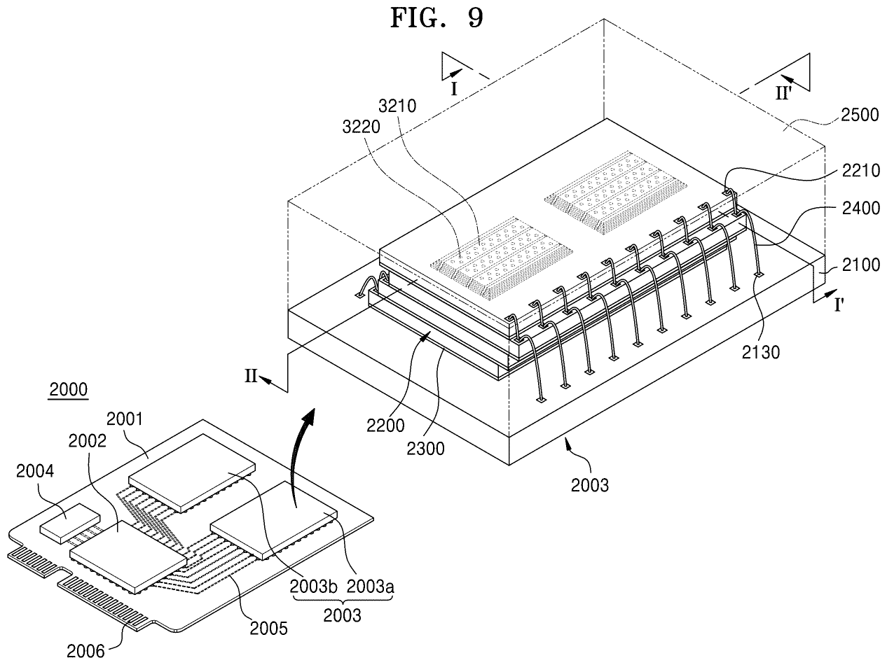

FIG. 9 is a perspective view of an electronic system including a semiconductor device according to some embodiments.

Referring to FIG. 9, according to some embodiments, an electronic system 2000 may include a main substrate 2001, a controller 2002, at least one semiconductor package 2003, and dynamic random access memory (DRAM) 2004, which are mounted on the main substrate 2001. The at least one semiconductor package 2003 and the DRAM 2004 may be connected to the controller 2002 by a plurality of wiring patterns 2005 formed in the main substrate 2001.

The main substrate 2001 may include a connector 2006 including a plurality of pins that are combined with an external host. The number and arrangement of pins in the connector 2006 may depend on a communication interface between the electronic system 2000 and the external host. In some embodiments, the electronic system 2000 may communicate with the external host according to any one interface, such as USB, peripheral component interconnect express (PCI-E), serial advanced technology attachment (SATA), and M-Phy for universal flash storage (UFS). In some embodiments, the electronic system 2000 may operate due to power supplied from the external host through the connector 2006. The electronic system 2000 may further include a power management integrated circuit (PMIC) configured to divide the power supplied from the external host between the controller 2002 and the semiconductor package 2003.

The controller 2002 may write data to the at least one semiconductor package 2003 or read data from the at least one semiconductor package 2003 and may increase an operating speed of the electronic system 2000.

The DRAM 2004 may be a buffer memory configured to reduce a difference in speed between the at least one semiconductor package 2003, which is a data storage space, and the external host. The DRAM 2004 included in the electronic system 2000 may operate as a kind of cache memory and provide a space for temporarily storing data during a control operation on the at least one semiconductor package 2003. When the DRAM 2004 is included in the electronic system 2000, the controller 2002 may further include a DRAM controller configured to control DRAM 2004 in addition to a NAND controller configured to control the at least one semiconductor package 2003.

The at least one semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 configured to electrically connect the plurality of semiconductor chips 2200 to the package substrate 2100, and a molding layer 2500 on (e.g., covering) the plurality of semiconductor chips 2200 and the connection structure 2400 on the package substrate 2100.

The package substrate 2100 may include a printed circuit board (PCB) including a plurality of package upper pads 2130. Each of the plurality of semiconductor chips 2200 may include an I/O pad 2210. The I/O pad 2210 may correspond to the I/O pad 1101 of FIG. 8A or FIG. 8B. Each of the plurality of semiconductor chips 2200 may include a plurality of gate stacks 3210 and a plurality of channel structures 3220. Each of the plurality of semiconductor chips 2200 may include at least one of the first transistor TR1 and the second transistor TR2 or TR22, which are described with reference to FIGS. 1 to 5.

In some embodiments, the connection structure 2400 may be a bonding wire configured to electrically connect the I/O pad 2210 to the package upper pad 2130. Accordingly, in the first and second semiconductor packages 2003a and 2003b, the plurality of semiconductor chips 2200 may be electrically connected to each other by using a bonding wire technique and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including TSVs instead of the connection structure 2400 for the bonding wire technique.

In some embodiments, the controller 2002 and the plurality of semiconductor chips 2200 may be included in one package. In some embodiments, the controller 2002 and the plurality of semiconductor chips 2200 may be mounted on an additional interposer substrate, which is different from the main substrate 2001, and the controller 2002 may be connected to the plurality of semiconductor chips 2200 by wirings formed in the interposer substrate.

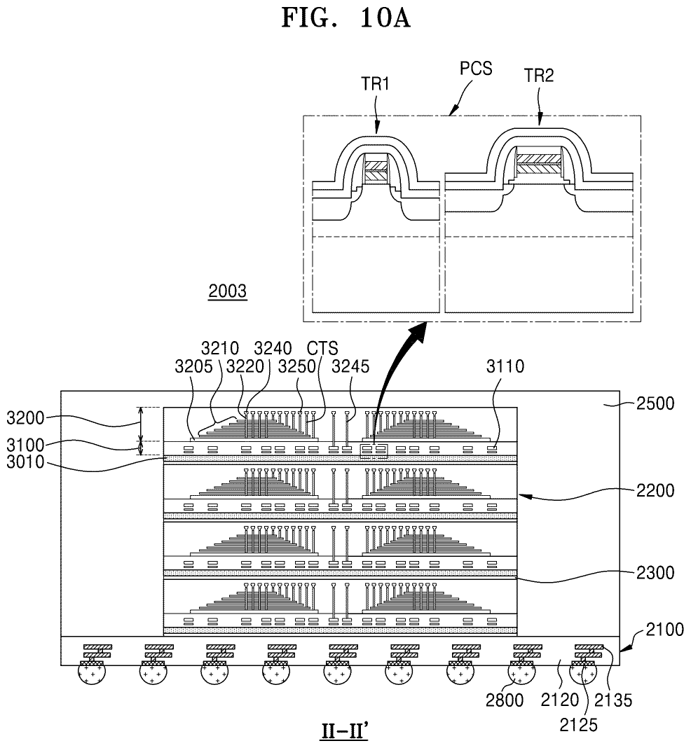

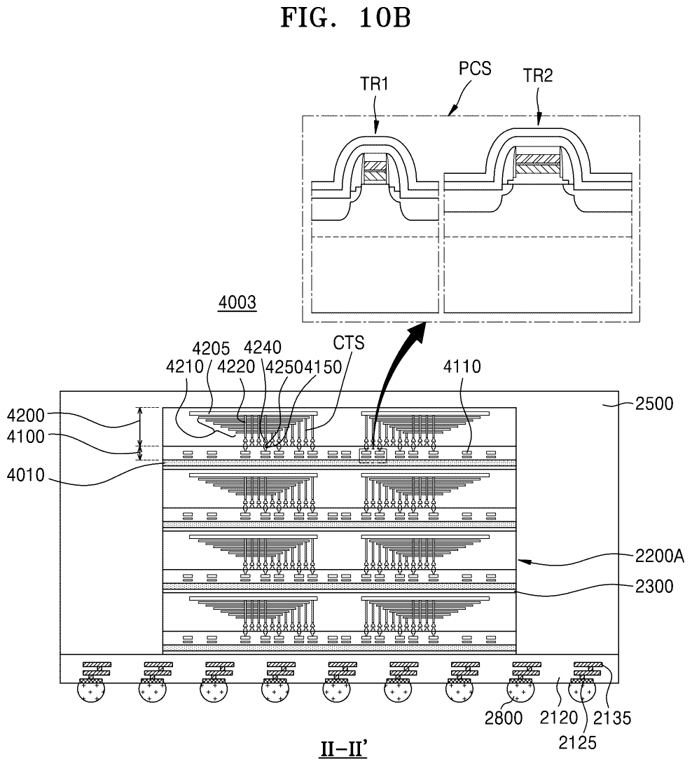

FIG. 10A is a cross-sectional view of a semiconductor package according to some embodiments. FIG. 10A schematically illustrates a configuration of the semiconductor package 2003, which is taken along line II-II′ of FIG. 9.

Referring to FIG. 10A, in the at least one semiconductor package 2003, a package substrate 2100 may be a PCB. The package substrate 2100 may include a package substrate body unit 2120, a plurality of package upper pads (refer to 2130 in FIG. 9) located on an upper surface of the package substrate body unit 2120, a plurality of lower pads 2125 located on a lower surface of the package substrate body unit 2120 or exposed at the lower surface of the package substrate body unit 2120, and a plurality of internal wirings 2135 configured to electrically connect the plurality of package upper pads 2130 to the plurality of lower pads 2125 in the package substrate body unit 2120. The plurality of package upper pads 2130 may be electrically connected to a plurality of connection structures (refer to 2400 in FIG. 9). The plurality of lower pads 2125 may be connected to a plurality of wiring patterns 2005 on the main substrate 2001 of the electronic system 2000 shown in FIG. 9, through a plurality of conductive connection units 2800.

Each of a plurality of semiconductor chips 2200 may include a semiconductor substrate 3010, a first structure 3100, and a second structure 3200. The first structure 3100 and the second structure 3200 may be sequentially stacked on the semiconductor substrate 3010. The first structure 3100 may include a peripheral circuit region including a plurality of peripheral wirings 3110. The first structure 3100 may include a peripheral circuit structure PCS including at least one of the first transistor TR1 and the second transistor TR2 or TR22, which are described with reference to FIGS. 1 to 5. FIG. 10A illustrates an example in which the first structure 3100 includes the peripheral circuit structure PCS including transistors having the same structures as the first transistor TR1 and the second transistor TR2 included in the semiconductor device 100 shown in FIG. 2, but the inventive concepts are not limited thereto. For example, the first structure 3100 may include the peripheral circuit structure PCS including transistors having the same structures as the first transistor TR1 and the second transistor TR22 included in the semiconductor device 200 shown in FIG. 4.

The second structure 3200 may include a common source line 3205, a gate stack 3210 on the common source line 3205, a channel structure 3220 passing through the gate stack 3210, and a bit line 3240 electrically connected to the channel structure 3220.

Each of the plurality of semiconductor chips 2200 may include through wirings 3245, which are electrically connected to a plurality of peripheral wirings 3110 of the first structure 3100 and extend into the second structure 3200. The through wiring 3245 may be outside the gate stack 3210. In other embodiments, the at least one semiconductor package 2003 may further include a through wiring passing through the gate stack 3210. Each of the plurality of semiconductor chips 2200 may further include I/O pads (refer to 2210 in FIG. 9), which are electrically connected to the plurality of peripheral wirings 3110 of the first structure 3100.

FIG. 10B is a cross-sectional view of a semiconductor package according to some embodiments. FIG. 10B schematically illustrates an example configuration of a semiconductor package 4003, which corresponds to a cross-section taken along line II-II′ of FIG. 9.

Referring to FIG. 10B, the semiconductor package 4003 may have substantially the same configuration as the semiconductor package 2003 described with reference to FIG. 10A. However, the semiconductor package 4003 may include a plurality of semiconductor chips 2200A. Each of the plurality of semiconductor chips 2200A may include a semiconductor substrate 4010, a first structure 4100 on the semiconductor substrate 4010, and a second structure 4200 bonded to the first structure 4100 by using a wafer bonding technique on the first structure 4100.

The first structure 4100 may include a peripheral circuit region including a peripheral wiring 4110 and a plurality of first bonding structures 4150. The first structure 4100 may include a peripheral circuit structure PCS including at least one of the first transistor TR1 and the second transistor TR2 or TR22, which are described with reference to FIGS. 1 to 5. FIG. 10B illustrates an example in which the first structure 4100 includes the peripheral circuit structure PCS including transistors having the same structures as the first transistor TR1 and the second transistor TR2 included in the semiconductor device 100 shown in FIG. 2, but the inventive concepts are not limited thereto. For example, the first structure 4100 may include the peripheral circuit structure PCS including transistors having the same structures as the first transistor TR1 and the second transistor TR22 included in the semiconductor device 200 shown in FIG. 4.

The second structure 4200 may include a common source line 4205, a gate stack 4210 between the common source line 4205 and the first structure 4100, and a channel structure 4220 passing through the gate stack 4210.

Also, each of the plurality of semiconductor chips 2200A may include a plurality of second bonding structures 4250, which are respectively electrically connected to a plurality of gate lines included in the gate stack 4210. For example, some of the second bonding structures 4250 may be connected to bit lines 4240, which are electrically connected to the channel structure 4220. Some others of the second bonding structures 4250 may be electrically connected to the gate lines through contact structures CTS.

The plurality of first bonding structures 4150 of the first structure 4100 may be in contact with and bonded to the plurality of second bonding structures 4250 of the second structure 4200. Bonded portions between the plurality of first bonding structures 4150 and the plurality of second bonding structures 4250 may include a metal (e.g., copper (Cu)), without being limited thereto.

In some embodiments, the connection of the plurality of semiconductor chips 2200 shown in FIG. 10A to each other and the connection of the plurality of semiconductor chips 2200A shown in FIG. 10B to each other may be enabled by a plurality of connection structures (refer to 2400 in FIG. 9), each of which is a bonding wire type. In some other embodiments, the electrical connection of the plurality of semiconductor chips 2200 shown in FIG. 10A to each other and the electrical connection of the plurality of semiconductor chips 2200A shown in FIG. 10B to each other may be enabled by connection structures including TSVs.

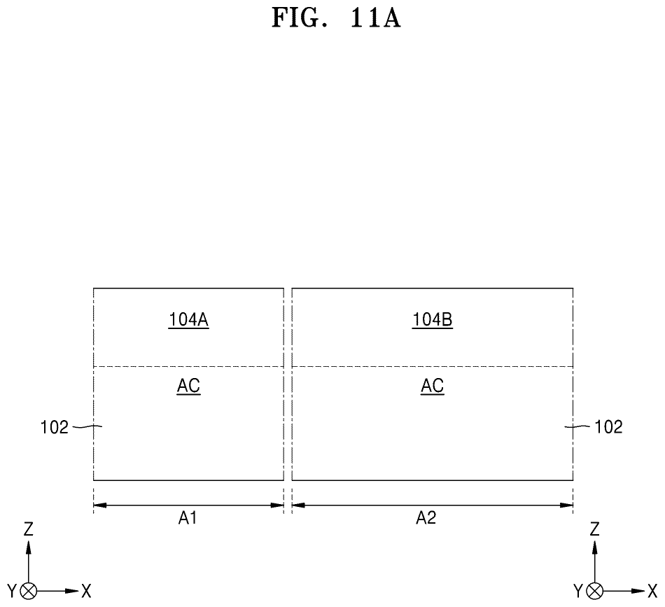

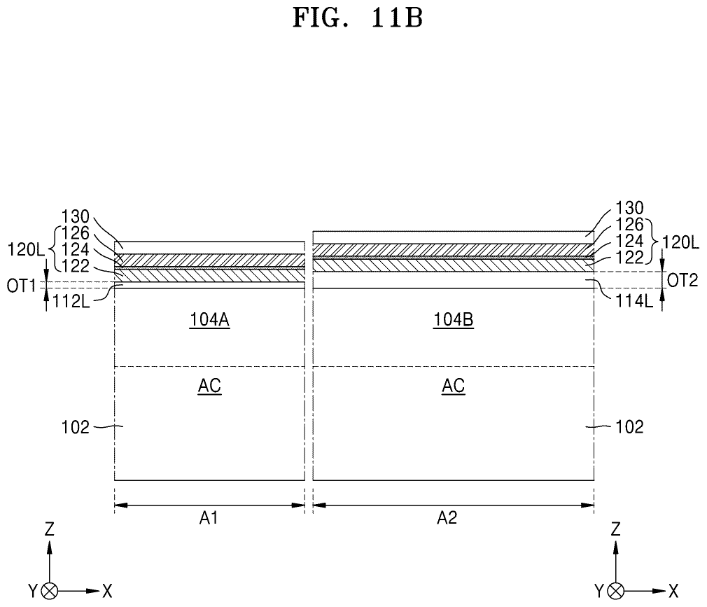

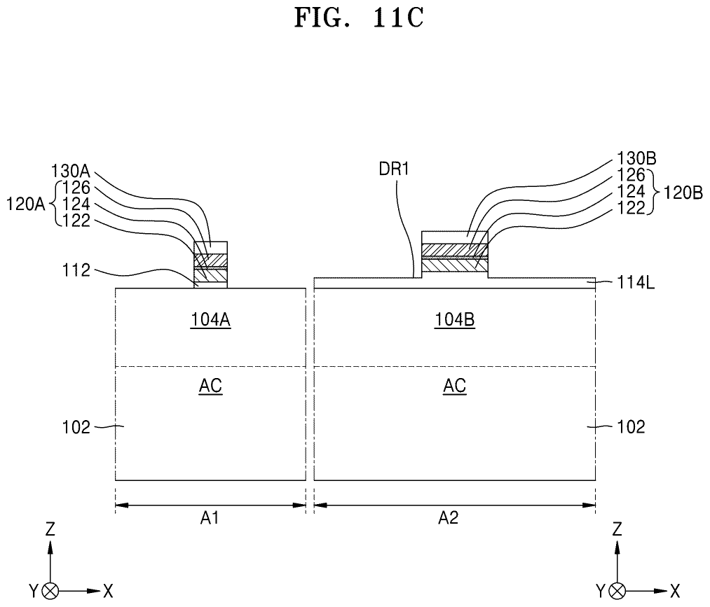

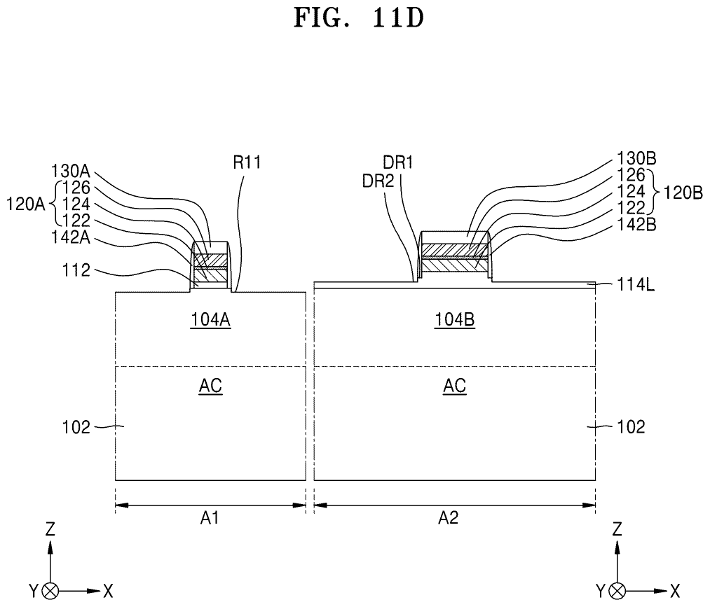

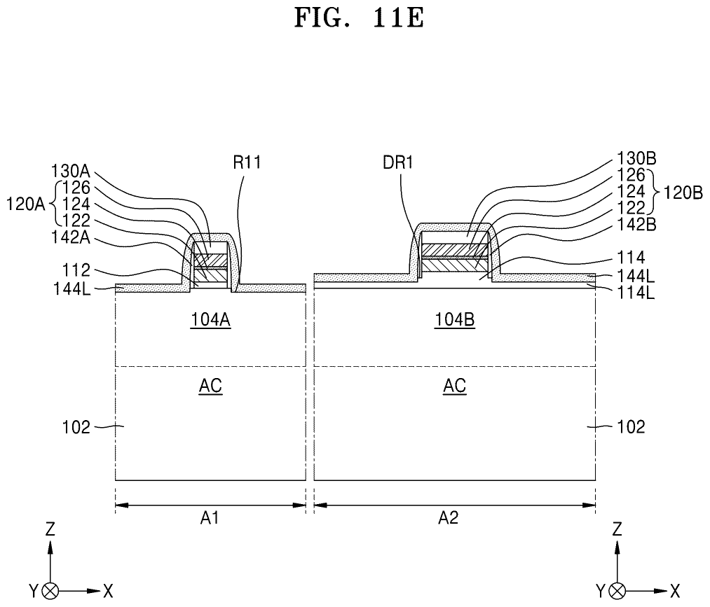

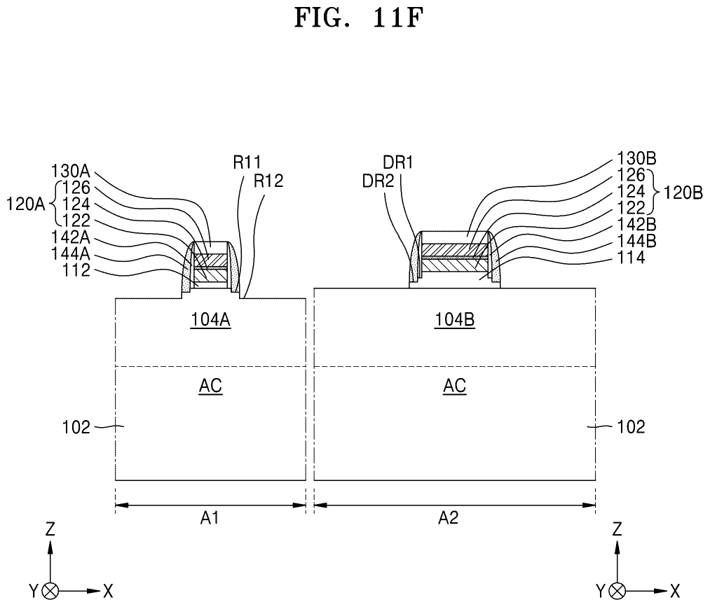

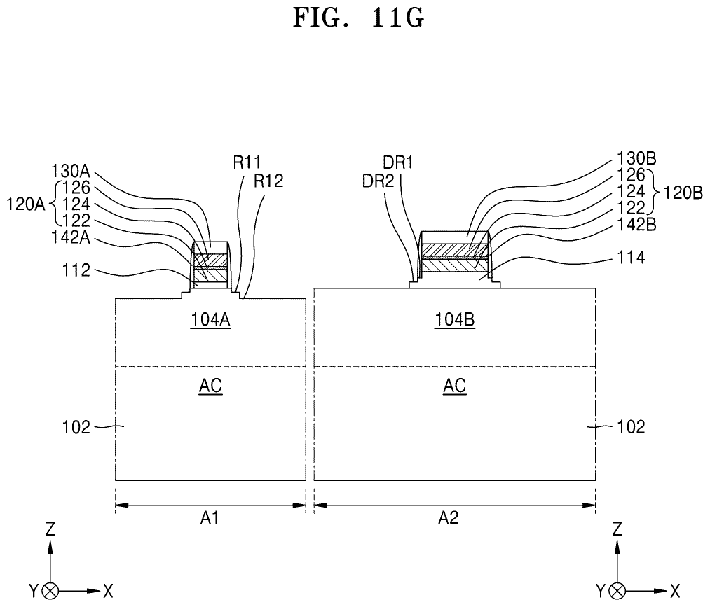

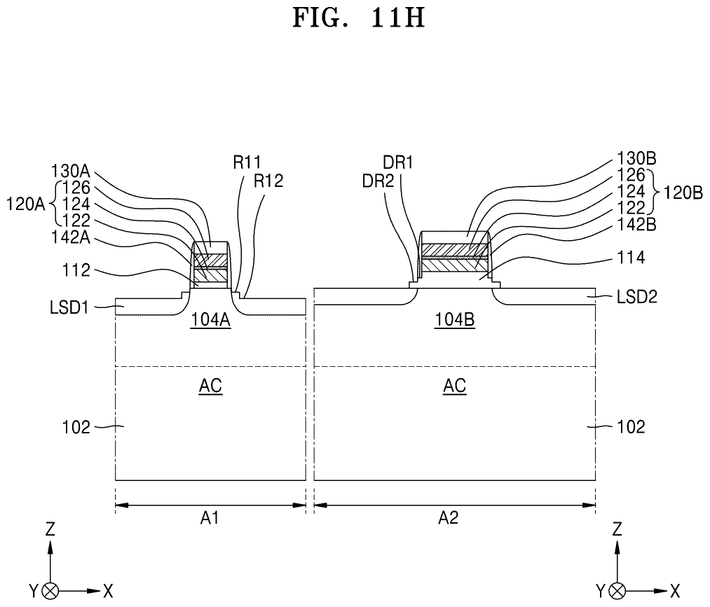

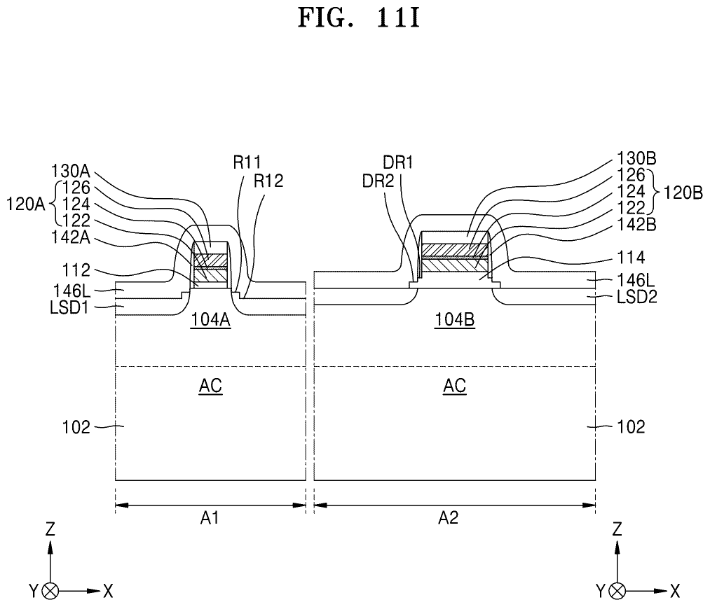

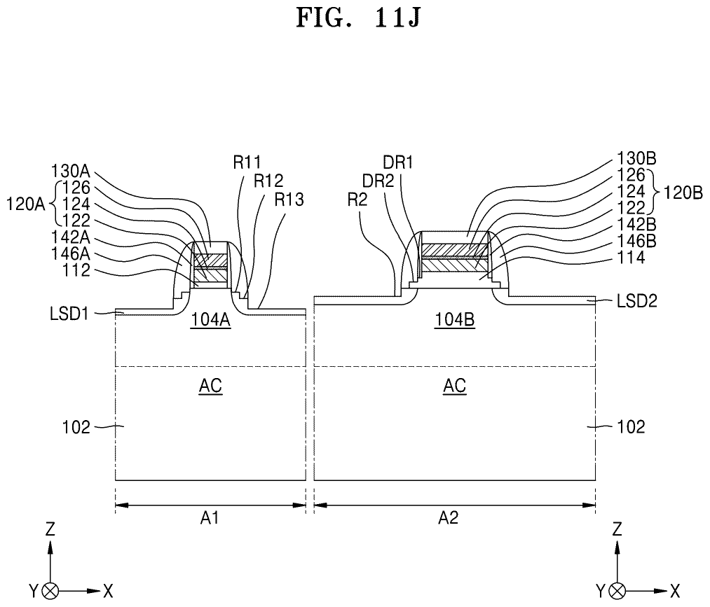

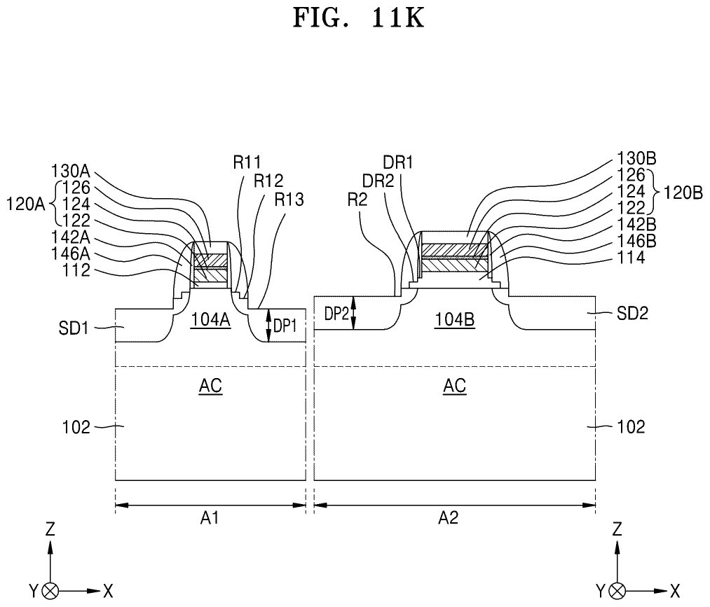

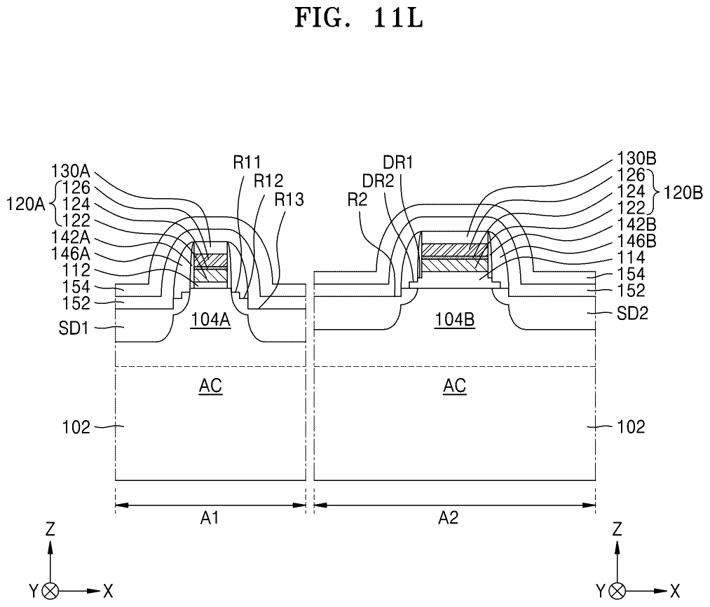

FIGS. 11A to 11L are cross-sectional views of a process sequence of a method of manufacturing a semiconductor device, according to some embodiments. A method of manufacturing the semiconductor device 100 shown in FIGS. 1 to 3B is described with reference to FIGS. 11A to 11L. In FIGS. 11A to 11L, the same reference numerals are used to denote the same elements as in FIGS. 1 to 3B, and thus, a detailed description thereof is omitted.

Referring to FIG. 11A, a plurality of active regions AC may be defined in a substrate 102 in a first region A1 and a second region A2, and a plurality of wells 104A and 104B may be formed in the plurality of active regions AC.

Referring to FIG. 11B, a first dielectric film 112L may be formed on the substrate 102 in the first region A1, and a second dielectric film 114L may be formed on the substrate 102 in the second region A2.

In a vertical direction (Z direction), the first dielectric film 112L may have a first thickness OT1, and the second dielectric film 114L may have a second thickness OT2 that is greater than the first thickness OT1. Constituent materials of the first dielectric film 112L and the second dielectric film 114L may be substantially the same as those of the first gate dielectric film 112 and the second gate dielectric film 114, which are described above.

A conductive layer 120L may be formed on each of the first dielectric film 112L and the second dielectric film 114L, and an insulating capping layer 130 may be formed on the conductive layer 120L. The conductive layer 120L may include a doped polysilicon film 122, a conductive barrier film 124, and a metal film 126, which are sequentially stacked on each of the first dielectric film 112L and the second dielectric film 114L. A constituent material of the insulating capping layer 130 may be the same as those of the first insulating capping layer 130A and the second insulating capping layer 130B, which are described above.

Referring to FIG. 11C, a portion of each of the insulating capping layer 130 and the conductive layer 120L may be etched in the first region A1 and the second region A2 of the resultant structure of FIG. 11B. Thus, a first gate electrode 120A and a first insulating capping layer 130A may be formed in the first region A1, and a second gate electrode 120B and a second insulating capping layer 130B may be formed in the second region A2. Subsequently, in the first region A1, a portion of the first dielectric film 112L may be etched to form a first gate dielectric film 112 including the remaining portion of the first dielectric film 112L. After the first gate dielectric film 112 is formed, a top surface of the substrate 102 may be exposed around the first gate electrode 120A. To form the first gate dielectric film 112 in the first region A1, during the etching of a portion of the first gate dielectric film 112, an upper portion of the second dielectric film 114L may be etched in the second region A2, and thus, a thickness of the second dielectric film 114L in the vertical direction (Z direction) may be reduced around the second gate electrode 120B. As a result, a first dielectric film step portion DR1 may be formed around the second gate electrode 120B.

Referring to FIG. 11D, an offset insulating film may be formed to conformally cover exposed surfaces in the first region A1 and the second region A2 in the resultant structure of FIG. 11C. Thereafter, the offset insulating film may be anisotropically etched in the first region A1 and the second region A2, and thus, a first offset insulating spacer 142A and a second offset insulating spacer 142B may be formed from the offset insulating film. During the anisotropic etching of the offset insulating film, an upper portion of the substrate 102 exposed around the first offset insulating spacer 142A may be etched in the first region A1, and thus, a first substrate step portion R11 may be formed on the top surface of the substrate 102 in the first region A1. Also, an upper portion of the second dielectric film 114L exposed around the second offset insulating spacer 142B may etched in the second region A2, and thus, a second dielectric film step portion DR2 may be formed on a top surface of the second dielectric film 114L.

Referring to FIG. 11E, in the resultant structure of FIG. 11D, a protective film 144L may be formed to conformally cover exposed surfaces in the first region A1 and the second region A2.

In some embodiments, the protective film 144L may include a silicon oxide film. In some embodiments, the protective film 144L may have a thickness in a range of about 5 nanometers (nm) to about 20 nm, for example, about 8 nm to about 12 nm, without being limited thereto. In some embodiments, the protective film 144L may be formed by using an atomic layer deposition (ALD) process.

Referring to FIG. 11F, the protective film 144L may be anisotropically etched in the first region A1 and the second region A2 in the resultant structure of FIG. 11E. Thus, a first protective spacer 144A on (e.g., covering) the first offset insulating spacer 142A may be formed on the first substrate step portion R11 in the first region A1, and a second protective spacer 144B on (e.g., covering) the second offset insulating spacer 142B may be formed on the second dielectric film step portion DR2 in the second region A2. During the anisotropic etching of the protective film 144L, an upper portion of the substrate 102 exposed around the first protective spacer 144A may be etched in the first region A1, and thus, a second substrate step portion R12 may be formed on the top surface of the substrate 102 in the first region A1. Also, the second dielectric film 114L exposed around the second protective spacer 144B may be removed in the second region A2 to expose the top surface of the substrate 102, and a second gate dielectric film 114 including the remaining portion of the second dielectric film 114L may be formed.

During the anisotropic etching of the protective film 144L in the first region A1 and the second region A2, a portion of the substrate 102 or a portion of the second gate dielectric film 114, which is exposed to the anisotropic etching atmosphere, may be damaged by the anisotropic etching atmosphere. However, a portion of the substrate 102 or the second gate dielectric film 114, which is damaged by the anisotropic etching atmosphere, may correspond to a position in a lateral direction (e.g., X direction in FIG. 11F) from a lower portion of each of the first gate electrode 120A and the second gate electrode 120B by a thickness of each of the first protective spacer 144A and the second protective spacer 144B in the lateral direction (e.g., X direction in FIG. 11F). In some embodiments, a thickness of each of the first protective spacer 144A and the second protective spacer 144B in the lateral direction (e.g., X direction in FIG. 11F) may be in a range of about 5 nm to about 20 nm (e.g., about 8 nm to about 12 nm), without being limited thereto. Accordingly, even when a portion of the substrate 102 or a portion of the second gate dielectric film 114, which is exposed to the anisotropic etching atmosphere, is damaged by the anisotropic etching atmosphere during the anisotropic etching of the protective film 144L in the first region A1 and the second region A2, a portion of the substrate 102 or the second gate dielectric film 114, which is damaged by the anisotropic etching atmosphere, may be outside an operating area of the first gate electrode 120A and the second gate electrode 120B. Thus, the damaged portion of the substrate 102 and/or the second gate dielectric film 114 may not adversely affect operations of transistors including the first gate electrode 120A and the second gate electrode 120B. Accordingly, reliability of transistors including the first gate electrode 120A and the second gate electrode 120B may improve.

Referring to FIG. 11G, the first protective spacer 144A and the second protective spacer 144B may be removed from the resultant structure of FIG. 11F by using a wet etching process. In some embodiments, the wet etching process may be performed by using an etchant including a hydrofluoric acid (HF) solution.

While the protective film 144L is being anisotropically etched in the process described with reference to FIG. 11F, a portion of the substrate 102 or a portion of the second gate dielectric film 114, which is exposed to an anisotropic etching atmosphere, may be damaged by the anisotropic etching atmosphere. In this case, the damaged portion of the substrate 102 and/or the second gate dielectric film 114 may be removed during the wet etching process described with reference to FIG. 11G.

Referring to FIG. 11H, an ion implantation process may be performed on the resultant structure of FIG. 11G by using the first and second insulating capping layers 130A and 130B and the first and second offset insulating spacers 142A and 142B as ion implantation masks, and thus, LDD source/drain regions (e.g., LSD1 and LSD2) may be formed in the substrate 102. The LDD source/drain regions (e.g., LSD1 and LSD2) may include a first LDD source/drain region LSD1 formed in the substrate 102 in the first region A1 and a second LDD source/drain region LSD2 formed in the substrate 102 in the second region A2. The first LDD source/drain region LSD1 and the second LDD source/drain region LSD2 may have substantially the same depth from the top surface of the substrate 102.

Referring to FIG. 11I, a main insulating film 146L may be formed to conformally cover exposed surfaces in the resultant structure of FIG. 11H. A constituent material of the main insulating film 146L may be same as that of each of the first main insulating spacer 146A and the second main insulating spacer 146B, which are described above. In some embodiments, the main insulating film 146L may be formed by using a chemical vapor deposition (CVD) process.

Referring to FIG. 11J, in the resultant structure of FIG. 11I, the main insulating film 146L may be anisotropically etched, and thus, a first main insulating spacer 146A may be formed in the first region A1, and a second main insulating spacer 146B may be formed in the second region A2.

During the anisotropic etching of the main insulating film 146L, an upper portion of the substrate 102 may be etched in the first LDD source/drain region LSD1 exposed around the first main insulating spacer 146A in the first region A1, and thus, a third substrate step portion R13 may be formed on the top surface of the substrate 102 in the first region A1. Also, an upper portion of the substrate 102 may be etched in the second LDD source/drain region LSD2 exposed around the second main insulating spacer 146B in the second region A2, and thus, a substrate step portion R2 may be formed on the top surface of the substrate 102 in the second region A2.

Referring to FIG. 11K, an ion implantation process may be performed on the resultant structure of FIG. 11J by using the first and second insulating capping layers 130A and 130B, the first and second offset insulating spacers 142A and 142B, and the first and second main insulating spacers 146A and 146B as ion implantation masks. Thus, a pair of first source/drain regions SD1 may be formed in the substrate 102 in the first region A1, and a pair of second source/drain regions SD2 may be formed in the substrate 102 in the second region A2. In the vertical direction (Z direction), a maximum depth DP1 of the pair of first source/drain regions SD1 may be substantially equal to a maximum depth DP2 of the pair of second source/drain regions SD2.

Referring to FIG. 11L, the first protective film 152 and a second protective film 154 may be sequentially formed on the resultant structure of FIG. 11K, and thus, the semiconductor device 100 shown in FIG. 2 may be manufactured.

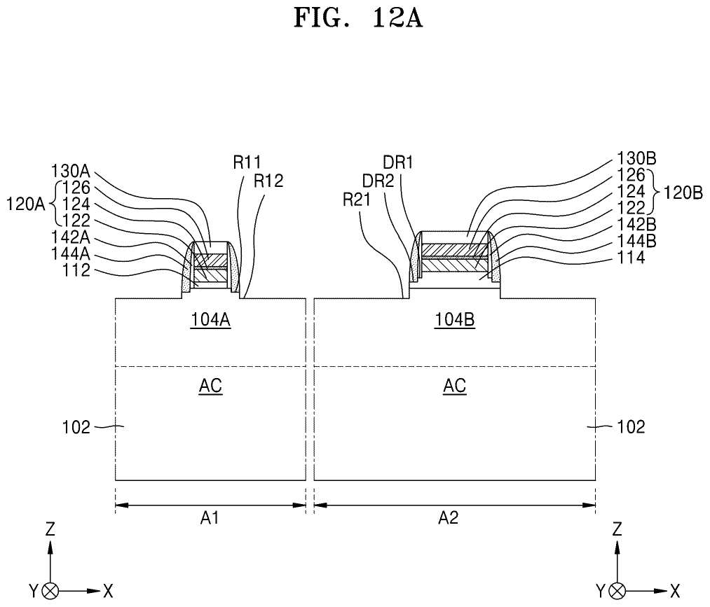

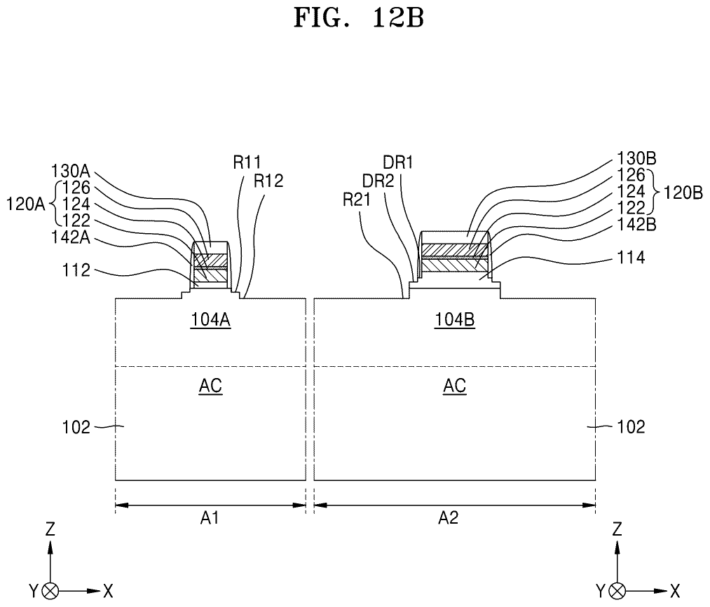

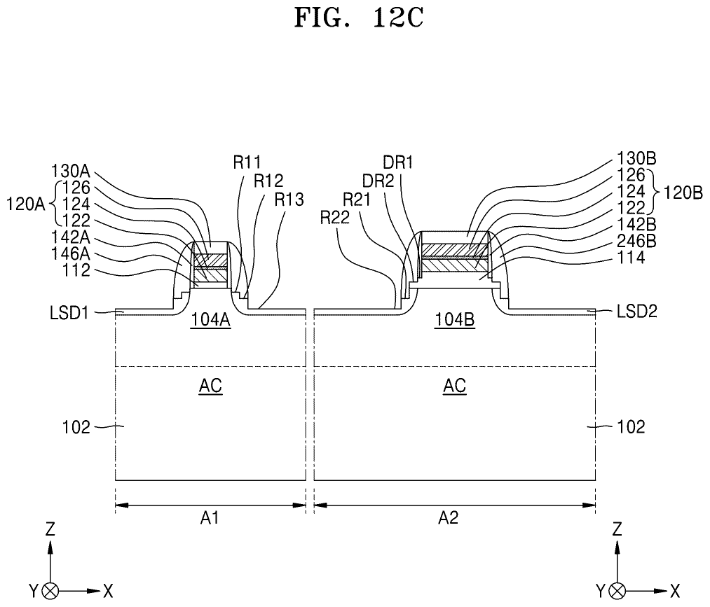

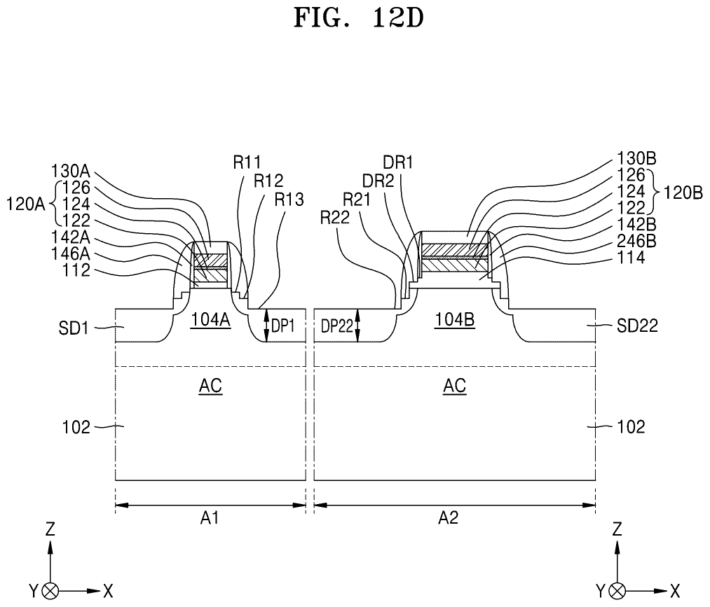

FIGS. 12A to 12D are cross-sectional views of a process sequence of a method of manufacturing a semiconductor device according to some embodiments. A method of manufacturing the semiconductor device 200 shown in FIGS. 4 and 5 is described with reference to FIGS. 12A to 12D. In FIGS. 12A to 12D, the same reference numerals are used to denote the same elements as in FIGS. 1 to 5, and thus, a detailed description thereof is omitted.

Referring to FIG. 12A, in a first region A1 and a second region A2, the processes described with reference to FIGS. 11A to 11F may be performed. However, in the process described with reference to FIG. 11F, during the anisotropic etching of a protective film 144L, an upper portion of a substrate 102 exposed around a first protective spacer 144A may be etched in the first region A1, and thus, a second substrate step portion R12 may be formed on a top surface of the substrate 102 in the first region A1, and the second dielectric film 114L exposed around a second protective spacer 144B may be exposed in the second region A2. Accordingly, the exposed upper portion of the substrate 102 may be further etched. As a result, a second gate dielectric film 114 including the remaining portion of the second dielectric film 114L may be formed in the second region A2, and a first substrate step portion R21 may be formed on the top surface of the substrate 102 around the second gate dielectric film 114.

Referring to FIG. 12B, the first protective spacer 144A and the second protective spacer 144B may be removed from the resultant structure of FIG. 12A by using a method similar to that described with reference to FIG. 11G. While the protective film 144L is being anisotropically etched in the process described with reference to FIG. 11F, a portion of the substrate 102 or a portion of the second gate dielectric film 114, which is exposed to an anisotropic etching atmosphere, may be damaged by the anisotropic etching atmosphere. In this case, while the first protective spacer 144A and the second protective spacer 144B are being removed as described with reference to FIG. 12B, the damaged portion of the substrate 102 and/or the second gate dielectric film 114 may be removed together.

Referring to FIG. 12C, by using a method similar to that described with reference to FIG. 11H, in the resultant structure of FIG. 12B, a first LDD source/drain region LSD1 may be formed in the substrate 102 in the first region A1, and a second LDD source/drain region LSD2 may be formed in the substrate 102 in the second region A2.

Afterwards, by using a method similar to the processes of forming the first main insulating spacer 146A and the second main insulating spacer 146B, which are described with reference to FIGS. 11I and 11J, a first main insulating spacer 146A may be formed in the first region A1, and a second main insulating spacer 246B may be formed in the second region A2. The second main insulating spacer 246B may be formed to have a surface that is on (e.g., that covers) the second dielectric film step portion DR2 and the first substrate step portion R21 and is in contact with the second dielectric film step portion DR2 and the first substrate step portion R21.

To form the first main insulating spacer 146A and the second main insulating spacer 246B, while the main insulating film 146L is being anisotropically etched as described with reference to FIG. 11J, an upper portion of the substrate 102 may be etched in the first LDD source/drain region LSD1 exposed around the first main insulating spacer 146A in the first region A1, and thus, a third substrate step portion R13 may be formed on the top surface of the substrate 102 in the first region A1. Also, an upper portion of the substrate 102 may be etched in the second LDD source/drain region LSD2 exposed around the second main insulating spacer 246B in the second region A2, and thus, a second substrate step portion R22 may be formed on the top surface of the substrate 102 in the second region A2.

Referring to FIG. 12D, by using a method similar to that described with reference to FIG. 11K, an ion implantation process may be performed on the resultant structure of FIG. 12C by using the first and second insulating capping layers 130A and 130B, the first and second offset insulating spacers 142A and 142B, and the first and second main insulating spacers 146A and 246B as ion implantation masks. Thus, a pair of first source/drain regions SD1 may be formed in the substrate 102 in the first region A1, and a pair of second source/drain regions SD22 may be formed in the substrate 102 in the second region A2. In a vertical direction (Z direction), a maximum depth DP1 of the pair of first source/drain regions SD1 may be substantially equal to a maximum depth DP22 of the pair of second source/drain regions SD22.

Thereafter, the processes described with reference to FIG. 11L may be performed, and thus, the semiconductor device 200 shown in FIGS. 4 and 5 may be manufactured.

Although the methods of manufacturing the semiconductor devices 100 and 200 shown in FIGS. 1 to 5 have been described with reference to FIGS. 11A to 12D, it will be understood that the semiconductor devices 100 and 200 and semiconductor devices having variously changed structures may be manufactured by applying various modifications and changes to the processes described with reference to FIGS. 11A to 12D within the scope of the inventive concepts.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While the inventive concepts have been particularly shown and described with reference to example embodiments thereof, it will be understood that various changes in form and details may be made therein without departing from the scope of the following claims.

What is claimed is:

1. A semiconductor device comprising:
a first gate dielectric film on a first channel top surface of a substrate, wherein the first channel top surface is in a first region of the substrate;
a first gate electrode on the first gate dielectric film;
first offset insulating spacers respectively on opposing sidewalls of each of the first gate dielectric film and the first gate electrode;
first main insulating spacers respectively on the opposing sidewalls of the first gate electrode, wherein the first offset insulating spacers are between the first main insulating spacers; and
a pair of first source/drain regions in the substrate on opposing sides of the first gate electrode,
wherein a top surface of each of the pair of first source/drain regions comprises at least two first-voltage substrate step portions having respective surfaces that are lower than the first channel top surface of the substrate in a vertical direction perpendicular to a bottom surface of the substrate, and
wherein the at least two first-voltage substrate step portions are at different levels from each other in the vertical direction.

2. The semiconductor device of claim 1, wherein, in the first region, the at least two first-voltage substrate step portions are spaced apart in a lateral direction parallel to the bottom surface of the substrate from a portion of the substrate that is overlapped by the first gate electrode in the vertical direction.

3. The semiconductor device of claim 1, wherein, in the first region, the at least two first-voltage substrate step portions are farther from the first channel top surface of the substrate than the first offset insulating spacers in a lateral direction parallel to the bottom surface of the substrate.

4. The semiconductor device of claim 1, wherein, in the first region, a bottom surface of at least one of the first offset insulating spacers is in contact with the first channel top surface of the substrate.

5. The semiconductor device of claim 1, wherein, in the first region, the at least two first-voltage substrate step portions comprise a first substrate step portion and a second substrate step portion that are overlapped by at least one of the first main insulating spacers in the vertical direction,
wherein the first substrate step portion is closer to the first channel top surface of the substrate than the second substrate step portion, and
wherein a first level of the first substrate step portion in the vertical direction is closer to a level of the first channel top surface of the substrate in the vertical direction than a second level of the second substrate step portion in the vertical direction.

6. The semiconductor device of claim 1, wherein, in the first region, the at least two first-voltage substrate step portions comprise a first substrate step portion, a second substrate step portion, and a third substrate step portion that are at different levels from each other in the vertical direction,
wherein each of the first substrate step portion and the second substrate step portion are overlapped by at least one of the first main insulating spacers in the vertical direction, and
wherein the third substrate step portion is spaced apart from the first channel top surface of the substrate, with the first substrate step portion and the second substrate step portion therebetween, and is farther from the first channel top surface of the substrate than the first main insulating spacers in a lateral direction parallel to the bottom surface of the substrate.

7. The semiconductor device of claim 1, further comprising:
a second gate dielectric film on a second channel top surface of the substrate, wherein the second channel top surface is in a second region of the substrate;
a second gate electrode on the second gate dielectric film;
second offset insulating spacers respectively on opposing sidewalls of each of the second gate dielectric film and the second gate electrode;
second main insulating spacers respectively on the opposing sidewalls of the second gate electrode, wherein the second offset insulating spacers are between the second main insulating spacers; and
a pair of second source/drain regions in the substrate on opposing sides of the second gate electrode,
wherein a thickness of the second gate dielectric film is greater than a thickness of the first gate dielectric film in the vertical direction,
wherein a width of the second gate electrode is greater than a width of the first gate electrode in a lateral direction parallel to the bottom surface of the substrate, and
wherein a top surface of each of the pair of second source/drain regions comprises at least one second-voltage substrate step portion having a surface that is at a lower level than the second channel top surface of the substrate in the vertical direction.

8. The semiconductor device of claim 7, wherein, in the second region, the at least one second-voltage substrate step portion is spaced apart in the lateral direction from a portion of the substrate that is overlapped by the second gate electrode in the vertical direction.

9. The semiconductor device of claim 7, wherein, in the second region, the at least one second-voltage substrate step portion is farther from the second channel top surface of the substrate than the second offset insulating spacers in the lateral direction.

10. The semiconductor device of claim 7, wherein, in the second region, a lowermost surface of at least one of the second main insulating spacers is in contact with a respective one of the pair of second source/drain regions.

11. The semiconductor device of claim 7, wherein, in the second region, a lowermost surface of each of the second main insulating spacers is at a lower level than the second channel top surface of the substrate in the vertical direction.

12. The semiconductor device of claim 7, wherein, in the second region, the at least one second-voltage substrate step portion comprises a first substrate step portion and a second substrate step portion that are at different levels from each other in the vertical direction,
wherein, in the second region, the first substrate step portion is overlapped by at least one of the second main insulating spacers in the vertical direction, and
wherein, in the second region, the second substrate step portion is spaced apart from the second channel top surface, with the first substrate step portion therebetween, and is farther from the second channel top surface than the second main insulating spacers in the lateral direction.

13. The semiconductor device of claim 7, wherein a width of the second gate dielectric film in the lateral direction increases toward the substrate in the vertical direction,
wherein a top surface of the second gate dielectric film comprises a dielectric film step portion,
wherein a level of the dielectric film step portion in the vertical direction is closer to the substrate than a level of an interface between the second gate dielectric film and the second gate electrode in the vertical direction and is farther from the bottom surface of the substrate than a level of the second channel top surface in the vertical direction,
wherein the dielectric film step portion is overlapped by at least one of the second main insulating spacers in the vertical direction, and
wherein a level of a lowermost surface of the at least one of the second main insulating spacers in the vertical direction is closer to the bottom surface of the substrate than the level of the dielectric film step portion in the vertical direction.

14. The semiconductor device of claim 7, wherein a top surface of the second gate dielectric film comprises a first dielectric film step portion and a second dielectric film step portion that are at different levels from each other in the vertical direction,
wherein the first dielectric film step portion is overlapped by at least one of the second offset insulating spacers in the vertical direction, and
wherein the second dielectric film step portion is farther from the second channel top surface of the substrate than at least one of the second main insulating spacers in the lateral direction and is overlapped by the at least one of the second main insulating spacers in the vertical direction.

15. A semiconductor device comprising:
a first transistor in a first region on a substrate, the first transistor having a first operating voltage; and
a second transistor in a second region on the substrate, the second transistor having a second operating voltage higher than the first operating voltage,
wherein the first transistor comprises:
a first gate dielectric film on a first channel top surface of the substrate;
a first gate electrode on the first gate dielectric film;
first offset insulating spacers respectively on opposing sidewalls of each of the first gate dielectric film and the first gate electrode;
first main insulating spacers respectively on the opposing sidewalls of the first gate electrode, wherein the first offset insulating spacers are between the first main insulating spacers; and
a pair of first source/drain regions in the substrate on opposing sides of the first gate electrode,
wherein the second transistor comprises:
a second gate dielectric film on a second channel top surface of the substrate, the second gate dielectric film having a greater thickness than the first gate dielectric film in a vertical direction perpendicular to a bottom surface of the substrate;
a second gate electrode on the second gate dielectric film, the second gate electrode having a width greater than a width of the first gate electrode in a lateral direction parallel to the bottom surface of the substrate;
second offset insulating spacers respectively on opposing sidewalls of each of the second gate dielectric film and the second gate electrode;
second main insulating spacers respectively on the opposing sidewalls of the second gate electrode, wherein the second offset insulating spacers are between the second main insulating spacers; and
a pair of second source/drain regions in the substrate on opposing sides of the second gate electrode,
wherein a top surface of at least one of the pair of first source/drain regions comprises at least two substrate step portions that are at different levels from each other in the vertical direction,
wherein a top surface of the second gate dielectric film comprises a dielectric film step portion, and
wherein a level of the dielectric film step portion in the vertical direction is closer to the substrate than a level of an interface between the second gate dielectric film and the second gate electrode in the vertical direction and is farther from the bottom surface of the substrate than a level of the second channel top surface in the vertical direction.

16. The semiconductor device of claim 15, wherein a thickness of the pair of first source/drain regions is equal to a thickness of the pair of second source/drain regions in the vertical direction.

17. The semiconductor device of claim 15, wherein, in the first region, the at least two substrate step portions comprise a first substrate step portion, a second substrate step portion, and a third substrate step portion that are at different levels from each other in the vertical direction,
wherein, in the first region, each of the first substrate step portion and the second substrate step portion is overlapped by at least one of the first main insulating spacers in the vertical direction, and
wherein, in the first region, the third substrate step portion is spaced apart from the first channel top surface, with the first substrate step portion and the second substrate step portion therebetween, and is farther from the first channel top surface than the first main insulating spacers in the lateral direction.

18. The semiconductor device of claim 15, wherein, in the second region, each of the pair of second source/drain regions comprises a first substrate step portion and a second substrate step portion that are at different levels from each other in the vertical direction,
wherein, in the second region, the first substrate step portion is overlapped by at least one of the second main insulating spacers in the vertical direction, and
wherein, in the second region, the second substrate step portion is spaced apart from the second channel top surface, with the first substrate step portion therebetween, and is farther from the second channel top surface than the second main insulating spacers in the lateral direction.

19. An electronic system comprising:
a main substrate;
a semiconductor device on the main substrate; and
a controller electrically connected to the semiconductor device on the main substrate,
wherein the semiconductor device comprises:
a cell region comprising a memory cell array; and
a peripheral circuit region comprising a plurality of circuits electrically connected to the memory cell array,
wherein the plurality of circuits comprise:
a first gate dielectric film on a first channel top surface of a substrate, wherein the first channel top surface is in a first region of the substrate;
a first gate electrode on the first gate dielectric film;
first offset insulating spacers respectively on opposing sidewalls of each of the first gate dielectric film and the first gate electrode;
first main insulating spacers respectively on the opposing sidewalls of the first gate electrode, wherein the first offset insulating spacers are between the first main insulating spacers; and
a pair of first source/drain regions in the substrate on opposing sides of the first gate electrode,
wherein a top surface of each of the pair of first source/drain regions comprises at least two first-voltage substrate step portions having respective surfaces that are lower than the first channel top surface of the substrate in a vertical direction perpendicular to a bottom surface of the substrate, and
wherein the at least two first-voltage substrate step portions are at different levels from each other in the vertical direction.

20. The electronic system of claim 19, wherein the main substrate comprises wiring patterns that electrically connect the semiconductor device to the controller,
wherein the plurality of circuits further comprise:
a second gate dielectric film on a second channel top surface of the substrate, wherein the second channel top surface is in a second region of the substrate;
a second gate electrode on the second gate dielectric film;
second offset insulating spacers respectively on opposing sidewalls of each of the second gate dielectric film and the second gate electrode;
second main insulating spacers respectively on the opposing sidewalls of the second gate electrode, wherein the second offset insulating spacers are between the second main insulating spacers; and
a pair of second source/drain regions in the substrate on opposing sides of the second gate electrode,
wherein the second gate dielectric film has a greater thickness than the first gate dielectric film in the vertical direction,
wherein the second gate electrode has a greater width than the first gate electrode in a lateral direction parallel to the bottom surface of the substrate, and
wherein a top surface of each of the pair of second source/drain regions comprises at least one second-voltage substrate step portion having a surface at a lower level than the second channel top surface in the vertical direction.
